(19) United States
(12) Patent Application Publication
(10) Pub. No.: US 2026/0354027 A1
(43) Pub. Date: Nov. 5, 2026

(54) OPTO-ELECTRO-MECHANICAL ASSEMBLY AND RELATED TOUCH-SENSING SYSTEM

(71) Applicant: UltraSense Systems, Inc., San Jose, CA (US)

(72) Inventors: Xiaoyue Jiang, San Jose, CA (US); Mo Li, Campbell, CA (US); Hao-Yen Tang, San Jose, CA (US)

(21) Appl. No.: 19/667,936

(22) Filed: May 5, 2026

Related U.S. Application Data
(60) Provisional application No. 63/800,120, filed on May 5, 2025.

(51) Int. Cl. H10N 30/20; H10N 30/88; H10N 39/00

(52) U.S. Cl. CPC H10N 30/202; H10N 30/88; H10N 39/00

(57) ABSTRACT

An opto-electro-mechanical assembly including a metallic cover member, a solid-state light source, at least one piezoelectric ultrasonic transducer (PUT), a solid light-transmitting and sound-transmitting member, and a circuit substrate to which the solid-state light source and the at least one PUT are electrically connected. The metallic cover member has an outer surface that can be touched by a finger. The PUT includes a piezoelectric capacitor. The solid light-transmitting and sound-transmitting member is interposed (1) between the solid-state light source and the metallic cover member and (2) between the at least one PUT and the metallic cover member. In some embodiments, the metallic cover member has a cover aperture that transmits light emitted from the solid-state light source toward the outer surface. Related touch-sensing systems, techniques, and processes are also disclosed.

### CROSS-REFERENCE TO RELATED APPLICATIONS

This application claims the benefit of U.S. Provisional Patent Application No.: 63/800,120 filed on May 5, 2025, entitled “OPTO-ELECTRO-MECHANICAL ASSEMBLY AND RELATED TOUCH-SENSING SYSTEM,” which is incorporated herein by reference in its entirety.

### BACKGROUND

Touch-sensing systems are a common interface to allow a user to interact with electrical devices such as smartphones, vehicles, computers, household appliances, industrial equipment, and other devices. Touch-sensing systems may employ capacitive-touch sensors. A capacitive-touch sensor may be sensitive to changes in capacitance caused by contact of an object (e.g., a finger) with a touch surface. In some cases, a capacitive-touch sensor may be sensitive to changes in capacitance caused by proximity of an object (e.g., a finger) to a touch surface. Accordingly, parameters such as the touch location may be determined. In some implementations, a touch-sensing system may be implemented as a slider; sliders are frequently found in applications where linear controls, such as volume controls, brightness controls, or controls of other parameters having a range of values are provided. In some implementations, a touch-sensing system may be implemented as one or more control buttons. Control buttons are typically found in applications requiring discrete user inputs such as turning the power (or another suitable functionality) on or off, or selecting one or more of several options (with each control button being associated with a respective option), and so on.

In one example, if each control button is associated with a respective letter or numeral, text may be input using control buttons. Herein, control buttons may sometimes be referred to as a button. Touch-sensing systems based on capacitive-touch sensors may replace mechanical sliders and mechanical control buttons. Although in widespread use, capacitive-touch sensors are limited in some respects. One shortcoming of capacitive-touch sensors is that they are preferably incorporated on glass or other non-metallic substrates. Capacitive-touch sensors are typically not employed with metallic substrates. Touch-sensing systems that may be implemented with a metallic substrate (e.g., a metallic cover member) that can be touched with a finger are desired for some applications. Such touch-sensing systems may be realized using piezoelectric ultrasonic transducers (PUTs) as the sensors. In such touch-sensing systems, it may be preferable to have illuminated indicia in the metallic cover members. Accordingly, improved opto-electro-mechanical assemblies and touch-sensing systems employing such improved opto-electro-mechanical assemblies are desired.

### BRIEF DESCRIPTION OF THE DRAWINGS

The disclosure may be more completely understood in consideration of the following detailed description of various embodiments of the disclosure in connection with the accompanying drawings, in which:

FIG. 1A is a schematic view of a portable electronic device in which an illustrative touch-sensing system may be implemented.

FIG. 1B is a schematic elevational view of an illustrative touch-sensing system (e.g., touch-sensing slider) in which the sensor assembly is adhered to the cover stack by an adhesive.

FIG. 1C is a schematic elevational view of an illustrative touch-sensing system (e.g., touch-sensing slider) in which the sensors are encapsulated in a molded package and a portion of the molded package is configured as the cover stack.

FIG. 2 is a schematic plan view of an array of touch-sensing elements (e.g., piezoelectric ultrasonic transducers (PUTs)) extending along a longitudinal direction.

FIG. 3 is a schematic plan view of an array of touch-sensing elements (e.g., PUTs) extending along a longitudinal direction and another direction.

FIG. 4 is a schematic elevational view of a sensor assembly according to some implementations, showing the arrangement of the electrodes of the PUTs and the electrical connections between these electrodes and input/output (I/O) electrodes (e.g., I/O pads).

FIG. 5A is a schematic elevational view of a sensor assembly according to some other implementations, showing the arrangement of the electrodes of the PUTs and the electrical connections between these electrodes and input/output (I/O) electrodes (e.g., I/O pads). The arrangement of FIG. 5A differs from the arrangement of FIG. 4 in that the PUTs share a common electrode (in the example shown, a common upper electrode). FIG. 5B is a schematic plan view of the array of PUTs as shown in elevational view in FIG. 5A.

FIG. 6A is a schematic elevational view of a sensor assembly according to some other implementations, showing the arrangement of the electrodes of the PUTs. The arrangement of FIG. 6A differs from the arrangements of FIGS. 4 and 5A that the PUT electrodes also function as I/O electrodes. FIG. 6B is a schematic elevational view of a touch-sensing system (e.g., touch-sensing slider) that incorporates the sensor assembly of FIG. 6A.

FIG. 7 is a schematic diagram of a touch-sensing system according to some implementations.

FIG. 8 is a flow diagram of a process of sensing touch according to some implementations.

FIG. 9A is a schematic timing diagram showing relationships among the signal portions of the signals received by the signal processor from the PUTs during a sensing event time frame.

FIG. 9B is a schematic timing diagram showing relationships among the sensing event time frames and the signal processing time frames during a touch determination period.

FIG. 10 is a flow diagram of a process of making a touch sensor device incorporating discrete (e.g., non-micromechanical) piezoelectric capacitors.

FIG. 11A is a schematic plan view of a cover member of an illustrative opto-electro-mechanical assembly. FIG. 11B is a schematic elevational view of the opto-electro-mechanical assembly.

FIGS. 12A and 12B are schematic plan views of a light-guide element as seen from a first side and a second side, respectively.

FIGS. 13A, 13B, and 13C, are schematic elevational views of respective sensor assemblies.

FIGS. 14A and 14B are schematic elevational views of respective opto-electro-mechanical assemblies.

FIGS. 15A, 15B, and 15C, are schematic elevational views of respective opto-electro-mechanical assemblies.

FIG. 16A is a schematic plan view of a touch-sensing element (e.g., piezoelectric ultrasonic transducer (PUT)).

FIGS. 16B and 16C are schematic plan views of arrays of touch-sensing elements (e.g., PUTs) extending along a longitudinal direction.

FIG. 17 is a schematic plan view of an array of PUTs including transmitting-type PUTs and receiving-type PUTs.

FIG. 18A is a schematic view of waves transmitted by transmitting-type PUTs, in which the waves transmitted from one of the PUTs are independent of the waves transmitted by another of the PUTs.

FIG. 18B is a schematic view of waves transmitted by transmitting-type PUTs, in which the waves interfere constructively to form a converging wavefront.

FIGS. 19A, 19B, and 19C, are schematic elevational views of respective opto-electro-mechanical assemblies.

FIGS. 20A and 20B are schematic elevational views of respective opto-electro-mechanical assemblies.

FIGS. 21A and 21B are schematic elevational views of respective opto-electro-mechanical assemblies.

FIGS. 22 and 23 are schematic elevational views of respective opto-electro-mechanical assemblies.

### DETAILED DESCRIPTION

The present disclosure relates to a touch-sensing system which incorporates an array of piezoelectric capacitors configured as piezoelectric ultrasonic transducers (PUTs) and piezoelectric force-measuring elements (PFEs). In some implementations, the touch-sensing system may be implemented as a virtual button in which the user input depends upon factors such as location of the user’s touch (e.g., touch by a user’s finger) and pressure and chronological pattern of the user’s touch (e.g., light touch and release, press and release, press and hold, multiple presses). In some implementations, the touch-sensing system may be implemented as a virtual slider in which the user’s finger slides along a predetermined surface and the user input depends on factors such as (1) the start position and/or the end position of the user’s finger sliding along the predetermined surface, and (2) the speed at which the finger slides along the predetermined surface. In some implementations, the touch-sensing system may be implemented as a virtual button at some times (“virtual button mode”) and as a virtual slider (“virtual slider mode”) at some other times. For example, in the virtual button mode, the touch-sensing system may receive user input indicating that a video player is to be activated. In a subsequent virtual slider mode, the touch-sensing system may receive a user input indicating a volume of the audio for the video player. A touch-sensing system can be used in various applications to provide a user-friendly and intuitive interface. For example, a touch-sensing system can be used in mobile devices (e.g., smartphones, tablet computers, laptop computers), household appliances (e.g., washing machines, dryers, light switches, kitchen appliances, remote control devices), medical devices, industrial appliances, office appliances, musical instruments, automobile interfaces, fitness equipment, home or office HVAC controls or automation, etc.

In this disclosure, the words “preferred” and “preferably” refer to embodiments of the invention that may afford certain benefits, under certain circumstances. However, other embodiments may also be preferred, under the same or other circumstances. Furthermore, the recitation of one or more preferred embodiments does not imply that other embodiments are not useful and is not intended to exclude other embodiments from the scope of the invention. The recitations of numerical ranges by endpoints include all numbers subsumed within that range (e.g., 1 to 5 includes 1, 1.5, 2, 2.75, 3, 3.80, 4, 5, etc.). For any method disclosed herein that includes discrete steps, the steps may be conducted in any feasible order. As appropriate, any combination of two or more steps may be conducted simultaneously.

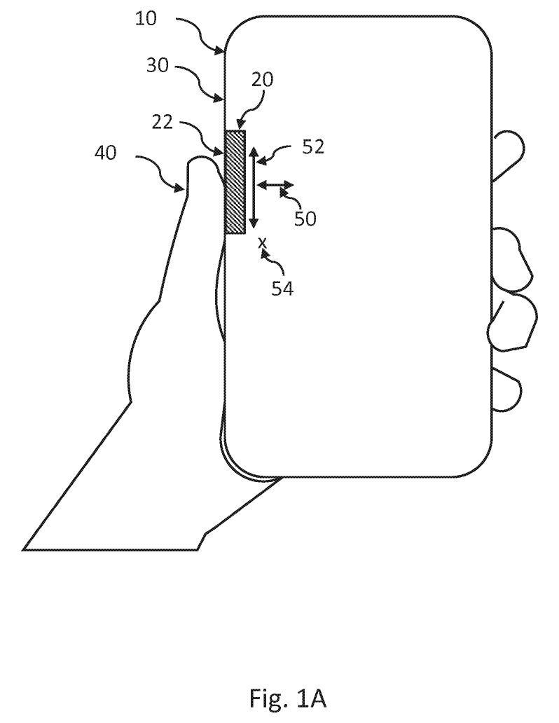

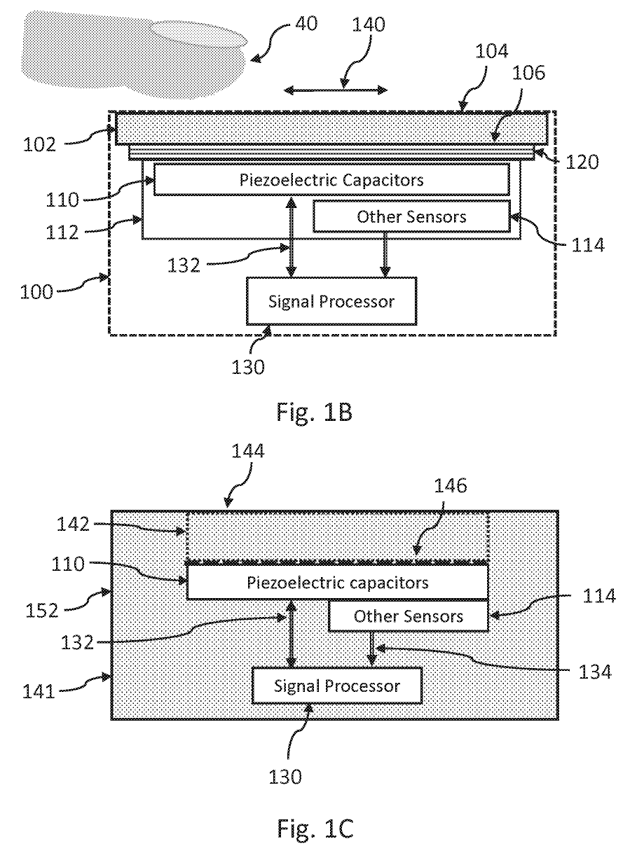

FIG. 1A is a schematic view of a portable electronic device 10 (e.g., a smartphone) including a touch-sensing system 20 in accordance with embodiments of the present technology. In the example shown, the touch-sensing system 20 is positioned along a side edge 30 of portable electronic device 10. The touch-sensing system 20 includes a cover stack having an outer surface 22. Outer surface 22 is exposed and can be touched by a user’s finger 40. A variety of user inputs are possible. In some examples, the user can apply a light touch and release, press and release, press and hold, or multiple presses (multiple instances of press and release). In these examples, the finger may apply a force along a transverse direction 50. In some other examples, the finger may swipe (slide) across the outer surface (while in contact with the outer surface) (e.g., along a longitudinal direction 52) and the user input may depend on factors such as (1) the start position and/or the end position of the user’s finger sliding along the predetermined surface, and (2) the speed at which the finger slides along the predetermined surface. In some implementations, the user may receive haptic feedback such as vibration or motion from the touch-sensing system 20. In some examples, the vibration may be along a transverse direction 50 or along the longitudinal direction 52 or another direction 54 perpendicular to the transverse direction 50 and the longitudinal direction 52 or a combination of any of the foregoing directions. The haptic feedback may vary in intensity, duration, and pattern, depending on the settings of the electronic device 10, the settings of the touch-sensing system 20, and the specific interaction being performed. In some embodiments, the touch-sensing system can be a discrete module coupled to (e.g., attached to) the frame of the electronic device 10 and electronically connected to control circuitry of the electronic device 10.

FIG. 1B is a schematic elevational view of an illustrative touch-sensing system 100. The touch-sensing system 100 includes a cover stack 102, a sensor assembly 110, and a signal processor 130. The cover stack has an outer surface 104 which can be touched by a finger 40. Cover stack 102 can be made from any robust material layer(s) through which ultrasound waves can propagate. Materials suitable for use in a cover stack include metals (aluminum, aluminum alloy, steel) and electrically non-conductive materials such as wood, glass, plastic, leather, fabric, and ceramic. The cover stack may be a single layer of material or may comprise multiple layers of materials. The cover stack may be electrically non-conductive. The cover stack may comprise any suitable material singly or in combination. In the example shown, sensors including sensor assembly 110 and other sensors 114 are encapsulated in a protective package 112. For example, sensor assembly 110 can include a MEMS device or can comprise discrete elements (e.g., piezoelectric member(s), substrate(s), wiring, electrode(s)), and be encapsulated in a package 112. Signal processor 130 is connected via a bus (or other signal interconnection) 132 to sensor assembly 110 and connected to the other sensors 114 via a bus (or other signal interconnection) 134. Signal processor 130 is configured to receive signals from sensor assembly 110 while sensor assembly 110 is active during a touch determination period. Sensor assembly 110 is mechanically coupled to cover stack 102 at its inner interface 106. In the example shown, sensor assembly 110, in its packaged form, is adhered to cover stack 102 at the inner interface 106 by an adhesive. Some examples of suitable adhesives are: double-sided tape, pressure sensitive adhesive (PSA), epoxy adhesive, or acrylic adhesive. The cover stack 102 has a longitudinal direction 140 along which a finger can touch and slide on outer surface 104.

FIG. 1C is a schematic elevational view of another illustrative touch-sensing system 141. The touch-sensing system 141 includes a sensor assembly 110, a signal processor 130, and a bus (or other signal interconnection) 132, as described with reference to FIG. 1B. In the example shown, sensor assembly 110, signal processor 130, bus 132, and other components (not shown) are encapsulated in a molded package 152. Materials that are typically employed for forming the molded package are robust materials such as plastic, metal, and ceramic. In this implementation, a portion of the molded package 152 is configured as a cover stack 142: cover stack 142 has an outer surface 144 which can be touched by a finger, and an inner interface 146 at which sensor assembly 110 is mechanically coupled. The cover stack portion 142 of molded package 152 is in the region between outer surface 144 and sensor assembly 110; sensor assembly 110 is configured to sense touch events that occur at the outer surface.

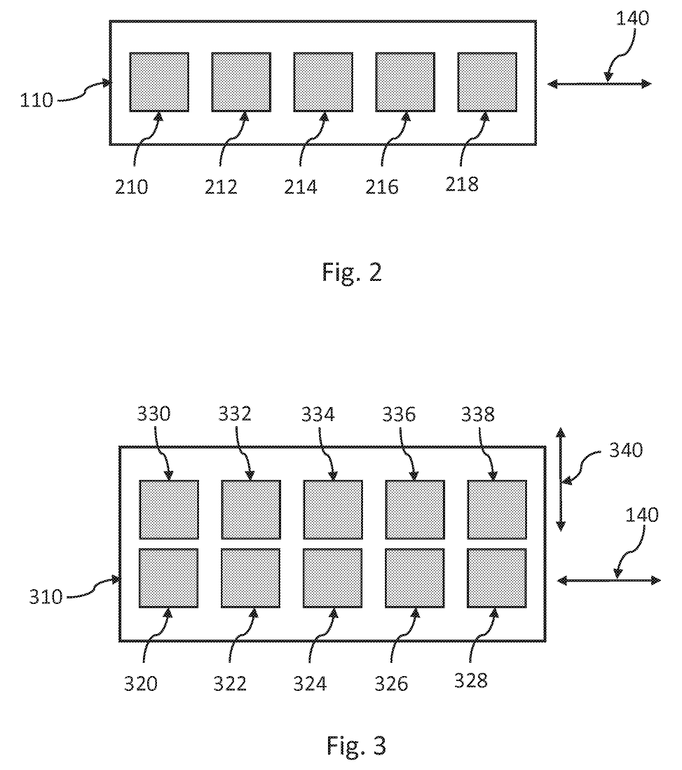

FIG. 2 is a schematic plan view of an illustrative sensor assembly 110, which includes an array of touch-sensing elements (e.g., 210, 212, 214, 216, 218) extending along a longitudinal direction 140. FIG. 3 is a schematic plan view of another illustrative sensor assembly 310, which includes an array of touch-sensing elements. Touch-sensing elements 320, 322, 324, 326, and 328 are arrayed along longitudinal direction 140. Touch-sensing elements 330, 332, 334, 336, and 338 are arrayed along longitudinal direction 140. Touch-sensing elements 320 and 330 are arrayed along another direction 340, which in the example shown is approximately perpendicular to longitudinal direction 140. Similarly, touch-sensing elements 322 and 332 are arrayed along other direction 340, and so on. The touch-sensing elements may be piezoelectric capacitors configured as piezoelectric ultrasonic transducers (PUTs) (including piezoelectric micromechanical ultrasonic transducers (PMUTs)), as explained herein. Additionally, in some implementations, piezoelectric capacitors may be configured as piezoelectric force-measuring elements (PFEs) (including piezoelectric micromechanical force-measuring elements (PMFEs)). In some implementations, micro-electro-mechanical systems (MEMS) technologies may be employed to make MEMS ICs (integrated circuits) that incorporate piezoelectric capacitors with a semiconductor chip. Micromechanical transducers (e.g., PMUTs, PMFEs) may be fabricated by MEMS technologies.

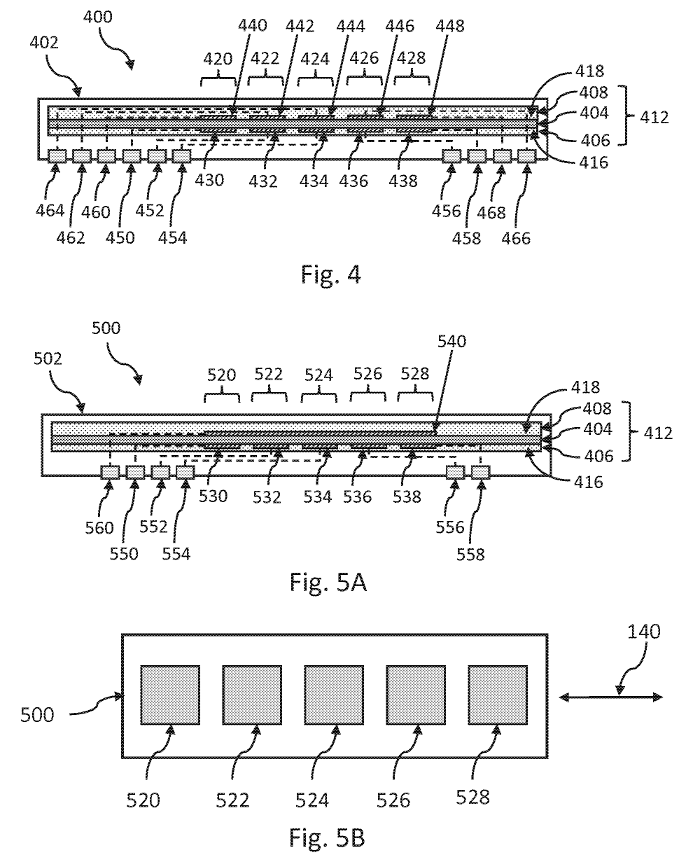

FIG. 4 is a schematic elevational view of a sensor assembly 400 according to some implementations. Sensor assembly 400 is encapsulated in a package 402. A piezoelectric member (e.g., layer or film) 404 extends across sensor assembly 400. In the example shown, mechanical layers 406 and 408 are adjacent to and attached to the piezoelectric member at its lower surface 416 and upper surface 418, respectively. Piezoelectric member 404, lower mechanical layer 406, and upper mechanical layer 408 constitute a piezoelectric stack 412. Lower mechanical layer 406 and/or upper mechanical layer 408 are optional and may be employed to modify the mechanical or other properties of piezoelectric stack 412, as compared to piezoelectric member 404 by itself. In some implementations, a substrate (e.g., Si substrate, dielectric substrate) may function as a mechanical layer upon which the piezoelectric layer is deposited or otherwise formed. Sensor assembly 400 includes PUTs 420, 422, 424, 426, and 428, which function as touch-sensing elements. Each PUT (piezoelectric capacitor) (420, 422, 424, 426, 428) includes a respective portion of the piezoelectric member (capacitor dielectric) 404, a respective lower electrode (430, 432, 434, 436, 438), and a respective upper electrode (440, 442, 444, 446, 448). The single piezoelectric member 404 is shared among these PUTs. In the example of sensor assembly 400, input/output (I/O) connections are made at the bottom of the sensor assembly. Ten I/O electrodes, serving the five PUTs, are shown: electrodes 450 and 460 connected to PUT 420, electrodes 452 and 462 connected to PUT 422, electrodes 454 and 464 connected to PUT 424, electrodes 456 and 466 connected to PUT 426, and electrodes 458 and 468 connected to PUT 428. Dotted lines show the interconnections between the I/O electrodes and the electrodes of the PUTs.

A free-standing piezoelectric member may be employed for discrete (e.g., non-micromechanical) piezoelectric capacitors. Suitable piezoelectric materials for a piezoelectric member include aluminum nitride, scandium-doped aluminum nitride, polyvinylidene fluoride (PVDF), lead zirconate titanate (PZT), potassium sodium niobate (KₓNa₁₋ₓNbO₃) (KNN), barium titanate (BaTiO₃) (BT), bismuth ferrite (BiFeO₃) (BFO), quartz, zinc oxide, lithium niobate, or bismuth sodium titanate (Bi_{0.5}Na_{0.5}TiO₃) (BNT). An example of a suitable piezoelectric material for a free-standing piezoelectric member is PZT. In the example shown, the cross-talk among nearby PUTs is sufficiently low so that multiple PUTs can share a common piezoelectric member (e.g., piezoelectric layer 404) with no appreciable degradation in performance. In some cases, manufacturing costs may be reduced by adopting designs in which multiple PUTs share a common piezoelectric member. In other cases, a separate piezoelectric member may be employed for each PUT. This may be accomplished by dicing a larger piezoelectric substrate into individual pieces.

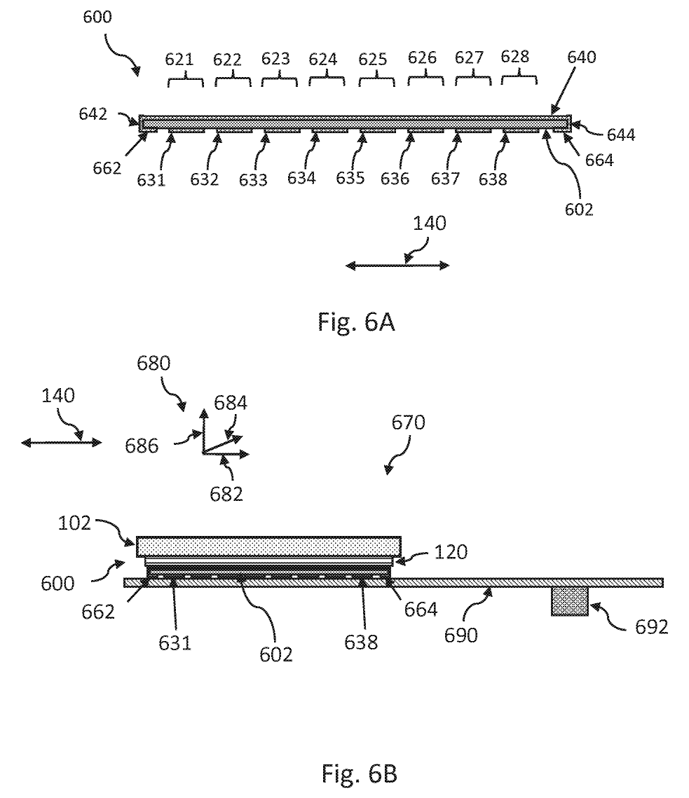

Each of the PUTs may be configured to operate in a transmitting mode or a receiving mode. For example, consider PUT 420 (FIG. 4). In a transmitting mode, upon application of a time-varying electric field between the electrodes (430, 440), the piezoelectric layer (piezoelectric member) 404 undergoes a contraction and expansion which results in mechanical motion (e.g., motion in the thickness direction, motion along a radial direction, shear motion, and/or flexural motion) of the piezoelectric member 404. For example, this time-varying electric field may be generated by the application of a time-varying voltage signal that is generated and amplified at the signal processor (692 of FIG. 6B) and transmitted to the PUTs. As a result of the mechanical motion, ultrasound waves (of a predetermined frequency) are transmitted in a normal direction (i.e., in the z-direction normal to the x-y plane in which the piezoelectric layer extends). If implemented in a touch-sensing system (e.g., 100), at least a portion of the transmitted ultrasound waves reach outer surface 104 of cover stack (cover member) 102, where the ultrasound waves may be attenuated by absorption by an object (e.g., a finger in contact with outer surface 104). At least a portion of the ultrasound waves are reflected back toward PUT 420. In a receiving mode, ultrasound waves (e.g., reflected ultrasound waves) of the predetermined frequency that are incident on the piezoelectric member 404 cause flexural motion of the piezoelectric member 404. As a result, time-varying voltage signals are generated between the electrodes (430, 440), which undergo signal conditioning (e.g., amplification, analog-to-digital conversion, other signal conditioning processes) before or after being received by a signal processor. The signal processor may determine, from the signals, whether a touch event has occurred, because of the greater attenuation of the ultrasound waves by the object touching the cover stack compared to when there is no touch. For example, the signal processor may determine (1) a touch event has occurred when the received signal corresponds to an attenuation of the ultrasound waves greater than a predetermined threshold, and (2) a touch event has not occurred when the received signal corresponds to an attenuation of the ultrasound waves smaller than a predetermined threshold.

In the foregoing description, piezoelectric capacitor 420 was described as being configured as a transmitting-type PUT and a receiving-type PUT. In addition, a piezoelectric capacitor (e.g., 420, 422, 424, 426, 428) may be configured as piezoelectric force-measuring elements (PFEs). For example, a piezoelectric capacitor may be configured as a transmitting-type PUT during a first time period, a receiving-type PUT during a second time period, and a PFE during a third time period. When a transient force is applied at cover stack 102 (e.g., by a finger touching or pressing cover stack 102 at outer surface 104), the transient force is transmitted to the neighboring PFEs (e.g., 420). The transient force causes a mechanical deformation of the PFE, which in turn causes a contraction (e.g., compressive stress) and/or expansion (e.g., tensile stress) of the piezoelectric member (e.g., 404). As a result, time-varying voltage signals are generated between the respective electrodes (e.g., 430 and 440) of a PFE. These time-varying voltage signals may undergo signal conditioning (e.g., amplification, analog-to-digital conversion, other signal conditioning processes) before or after being received by the signal processor. The signal processor may estimate (1) a transient strain (e.g., transient strain at the piezoelectric member) or (2) a transient applied force (e.g., transient force applied by a finger at the outer surface of the cover stack) from the time-varying voltage signals. The PFEs are sensitive to transient strain and may be distinguished from other elements that are sensitive to steady-state strain such as a strain gauge.

FIG. 5A is a schematic elevational view of a sensor assembly 500 according to some other implementations. Sensor assembly 500 is encapsulated in a package 502. Sensor assembly 500 includes PUTs 520, 522, 524, 526, and 528, which function as touch-sensing elements. The arrangement of FIG. 5A differs from the arrangement of FIG. 4 in that the PUTs share a common electrode (in the example shown, a common upper electrode 540). Accordingly, there are six I/O electrodes serving the five PUTs: electrode 560 connected to common PUT electrode (upper electrode) 540, electrode 550 connected to bottom electrode 530 of PUT 520, electrode 552 connected to bottom electrode 532 of PUT 522, electrode 554 connected to bottom electrode 534 of PUT 524, electrode 556 connected to bottom electrode 536 of PUT 526, and electrode 558 connected to bottom electrode 538 of PUT 528. Dotted lines show the interconnections between the I/O electrodes and the electrodes of the PUTs. The implementation of FIG. 5A reduces the number of PUT electrodes, I/O electrodes, and PUT-to-I/O interconnections, compared to the implementation of FIG. 4. FIG. 5B is a schematic plan view of the array of PUTs as shown in elevational view in FIG. 5A. The PUT array extends along a longitudinal direction 140.

FIG. 6A is a schematic elevational view of a sensor assembly 600 according to some other implementations. Sensor assembly 600 includes a piezoelectric member 602 in the form of a free-standing film. In the example shown, mechanical layers have been omitted. In the example shown, sensor assembly 600 is not encapsulated in any package. A common upper PUT electrode 640 is shared among the PUTs 621, 622, 623, 624, 625, 626, 627, and 628. Each of the PUTs includes a respective lower electrode (631, 632, 633, 634, 635, 636, 637, and 638). Upper electrode 640 wraps around from the top to the bottom of the piezoelectric member 602. Electrode portion 642 wraps around piezoelectric member 602 along its left edge to an electrode extension 662 near the bottom left of piezoelectric member 602. Similarly, electrode portion 644 wraps around piezoelectric member 602 along its right edge to an electrode extension 664 near the bottom right of piezoelectric member 602. Note that one of these electrode extensions (662 or 664) may be omitted. The arrangement of FIG. 6A differs from the arrangements of FIGS. 4 and 5A in that the PUT electrodes also function as I/O electrodes. The PUT array extends along longitudinal direction 140.

FIG. 6B is a schematic elevational view of touch-sensing system 670 that incorporates sensor assembly 600 of FIG. 6A. In the example shown, sensor assembly 600 is mounted to a circuit board substrate 690. For example, all PUT electrodes (e.g., 662, 631, 638, 664, etc.) are bonded (e.g., bonded by soldering (solder-bonded), bonded by conductive adhesive) directly to respective electrodes on the circuit board substrate 690. Sensor assembly 600 is adhered to cover stack 102 via an adhesive 120 at the upper surface of sensor assembly 600. A signal processor 692 (e.g., the signal processor may be implemented as an application-specific integrated circuit ASIC)) is also mounted to the circuit board substrate and is electrically coupled to the PUTs (e.g., configured to send signals to and receive signals from the PUTs). The PUT array extends along longitudinal direction 140. An orthogonal coordinate system 680 includes an x-axis 682 (shown as being approximately parallel to the longitudinal direction 140), a y-axis 684 (directed into the page), and a z-axis 686 (normal to the plane formed by the x- and y-axes). In the example shown, piezoelectric member 602 extends along the x- and y-axes. Accordingly, z-axis 686 is approximately normal to the plane of the piezoelectric member 602.

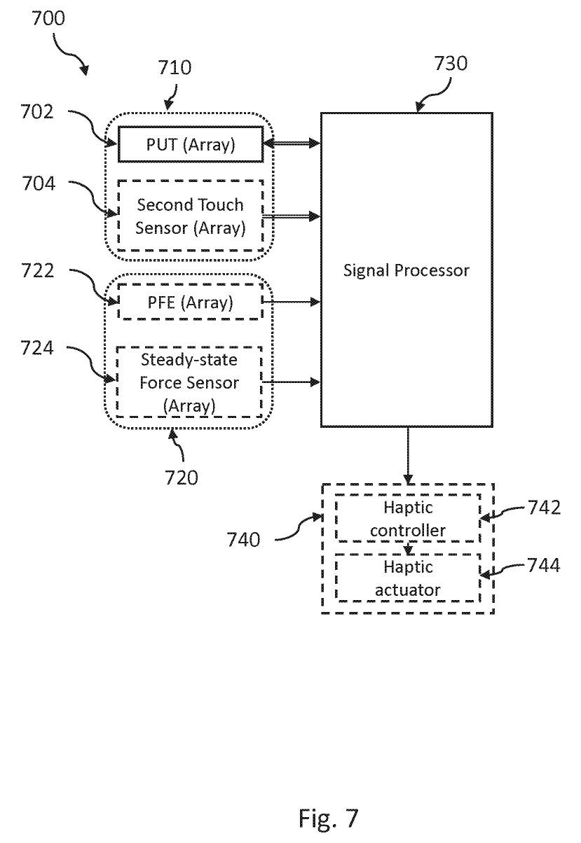

FIG. 7 , is a schematic diagram illustrating certain signal-generating and signal-processing aspects of a touch-sensing system 700 in accordance with some embodiments. Touch-sensing system 700 includes piezoelectric capacitors that are mechanically coupled to the cover stack, as described elsewhere herein. The piezoelectric capacitors include a first array of piezoelectric capacitors configured as PUTs (702) and optionally, a second array of piezoelectric capacitors configures as PFEs (722). In some implementations, there may be only one PUT and/or only one PFE (in such a case, there is not array of PUTs or PFEs). In some implementations, the touch-sensing system 700 may include a second touch sensor (or sensor array) 704 and/or a steady-state force sensor (or sensor array) 724. The data output from the PFE (array), second touch sensor (array) or a steady-state force sensor (array) may be useful, in combination with outputs from PUT (array) 702, in determining touch events with greater confidence and/or a greater rejection of false positives. In some examples, the second touch sensor array may be an array of capacitive touch sensors. Steady-state force sensors are distinguishable from transient force sensors such as PFEs. Steady-state force sensors provide signals that are responsive to the applied force under steady-state conditions; steady-state force sensors continue to provide the signal as long as the applied force is on. Transient force sensors (e.g., PFEs) provide signals that are responsive to changes in applied force (e.g., change from little or no force to a force applied by a finger during finger touch or finger press). These signals dissipate quite quickly (e.g., in a range of 10 ms to 100 ms, in a range of 1 ms to 10 ms, or less than 1 ms) even if the applied force continues to be on. Some examples of steady-state force sensors are strain gauges and parallel-plate force sensors. The PUT array 702 and the optional secondary touch sensor array 704 may be regarded as the touch-sensing portion 710 of system 700. The PFE array 722 and the steady-state force sensor array 724 may be regarded as the force-sensing portion 720 of system 700. These sensor arrays (702, 704, 722, 724) are coupled to the signal processor 730. The signal and data flow between the sensor arrays may be in monodirectional (e.g., signals representing measurement data from sensor array to the signal processor) or bidirectional (e.g., signals representing measurement data from sensor array to the signal processor, and signals for driving the transducers from the signal processor to the transducer (sensor) array). For example, the voltage signals for driving the transmitting-type PUTs may be generated and amplified at the signal processor 730 and transmitted to the PUT array 702.

In some implementations of FIG. 7, the touch-sensing system further comprises a haptic module 740. The haptic module comprises a haptic controller 742 and a haptic actuator 744. The signal processor 730 may generate haptic feedback commands (e.g., in response to a finger touch input at the cover stack, as sensed by any one or more of the sensors 702, 704, 722, and 724). In addition, the signal processor 730 may generate haptic feedback commands in accordance with other inputs (e.g., inputs from an external system). The haptic controller 742 drives the haptic actuator in accordance with the haptic feedback commands from the signal processor. The haptic actuator may be any suitable actuator known in the art such as an eccentric rotating mass (ERM) motor or a linear resonant actuator (LRA). Additionally, a voice coil motor may also be employed as a haptic actuator. The haptic actuator is preferably configured to be vibrationally coupled to the cover stack where the vibration may be felt by a finger.

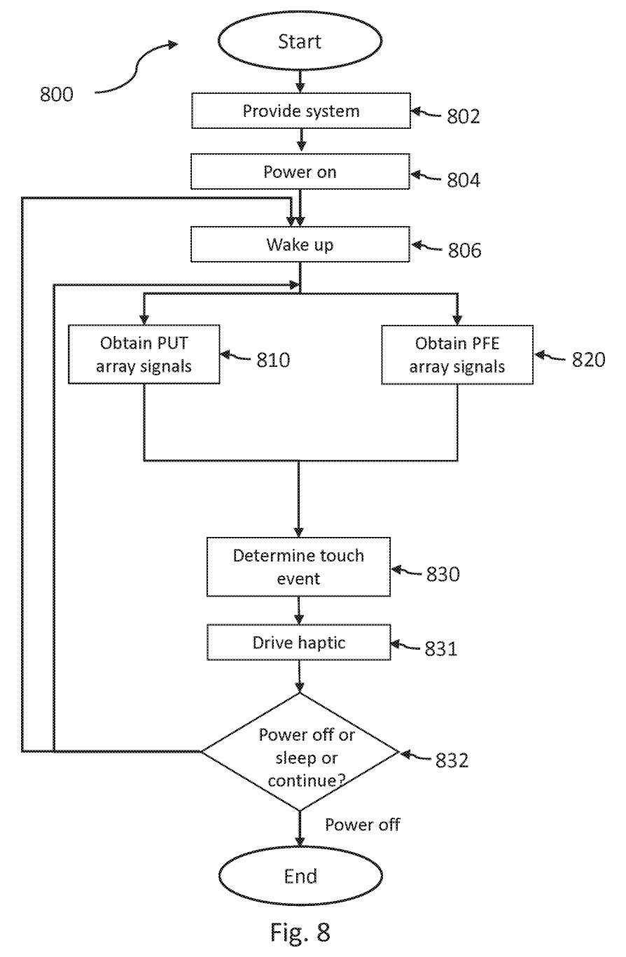

FIG. 8 is a flow diagram of process 800 of sensing touch according to some implementations. Process 800 includes stages 802, 804, 806, 810, 820, 830, 831, and 832. Stage 802 includes providing a touch-sensing system (e.g., 100 of FIGS. 1B, 141 of 1C,7 700 ). Stage 804 includes turning on the touch-sensing system (e.g., supplying electrical power to the system, initializing the system). Upon completion of stage 804, the touch-sensing system may be in a lower-power mode (e.g., the system may be in either a higher-power mode or a lower-power mode). At stage 806, the touch-sensing system transitions from the lower-power mode to a higher-power mode, in which the sensors of the touch-sensing system are active. For example, this transition to the higher-power mode may be triggered by a signal (e.g., “wake-up signal”) from an external source. For example, this transition to the higher-power mode may be triggered by a signal (e.g., “wake-up signal”) from one or more of the sensors of the touch-sensing system that stays on in the lower-power mode. After the sensors have been activated, there are left and right branches in the process 800 relating to operation of the PUTs and the PFEs, respectively. The left and right branches may be carried out concurrently or sequentially. The left branch includes stage 810. Stage 810 may include: (1) transmitting, by the transmitting-type PUTs, ultrasound waves towards the cover stack in a predetermined frequency range, with the ultrasound waves propagating along a normal direction (686, FIG. 6B) approximately normal to a plane of the one or more piezoelectric members; (2) receiving, by the receiving-type PUTs, the ultrasound waves from the cover stack in the predetermined frequency range; and (3) generating the PUT array signals in accordance with the ultrasound waves received at the receiving-type PUTs. For example, the PUT array signals are transmitted from the PUTs (PUT array) to the signal processor. For example, the PUT array signals may undergo amplification, analog-to-digital conversion, and any other suitable signal conditioning (e.g., high-pass filtering, subtraction of noise), at the signal processor (and/or elsewhere). The right branch includes stage 820. Stage 820 may include: obtaining PFE array signals from voltage signals generated at the PFEs in response to a low-frequency deformation of the cover stack. For example, the PFE array signals are transmitted from the PFEs (PFE array) to the signal processor. For example, the PFE array signals may undergo amplification, analog-to-digital conversion, and any other suitable signal conditioning (e.g., high-pass filtering, subtraction of noise), at the signal processor (and/or elsewhere).

Stage 830 includes determining a touch event (e.g., determining whether a touch event has occurred (or that a detected event is a false positive event); in the case of a touch-sensing system comprising an array of PUTs, calculating PUT centroid data from the PUT data and obtaining an estimated touch position on the cover stack from the PUT centroid data; or in the case of a touch-sensing system comprising an array of PUTs and an array of PFEs, calculating PUT centroid data from the PUT data, calculating PFE centroid data from the PFE data, combining the PUT data and the PFE data in suitable combination ratios, and obtaining an estimated touch position on the cover stack from the combined centroid data). A touch event may include a finger touch, including a finger press, a finger slide across the cover member, and repetitions of any of the foregoing. False positives include false detection of touch events arising from other factors such as objects contacting the cover stack or temperature changes. Some examples of foreign objects that can cover or contact the cover member include water, sweat, other liquids, ice, snow, and foods.

In some implementations, stage 831 may be optional. Stage 831 may be carried out in touch-sensing systems that comprise a haptic module, in which the haptic module comprises a haptic actuator and a haptic controller, with the haptic actuator being vibrationally coupled to the cover stack. Stage 831 includes driving, by the haptic controller, the haptic actuator in accordance with haptic feedback commands from the signal processor or another suitable source of haptic feedback commands (e.g., a processor outside of the touch-sensing system).

At stage 832, three or more options are possible. A first option is that the touch-sensing system powers off. For example, this may occur if the power supply is turned off or a battery power source is depleted. A second option is that the touch-sensing system goes into a lower-power mode (e.g., the touch sensor is inactive in the lower-power mode) when at least one condition is met, such as if no touch is detected for a certain time period or upon completion of a predetermined time period. Otherwise, a third option is that stages 810, 820, 830, 831, 832 are repeated for additional time.

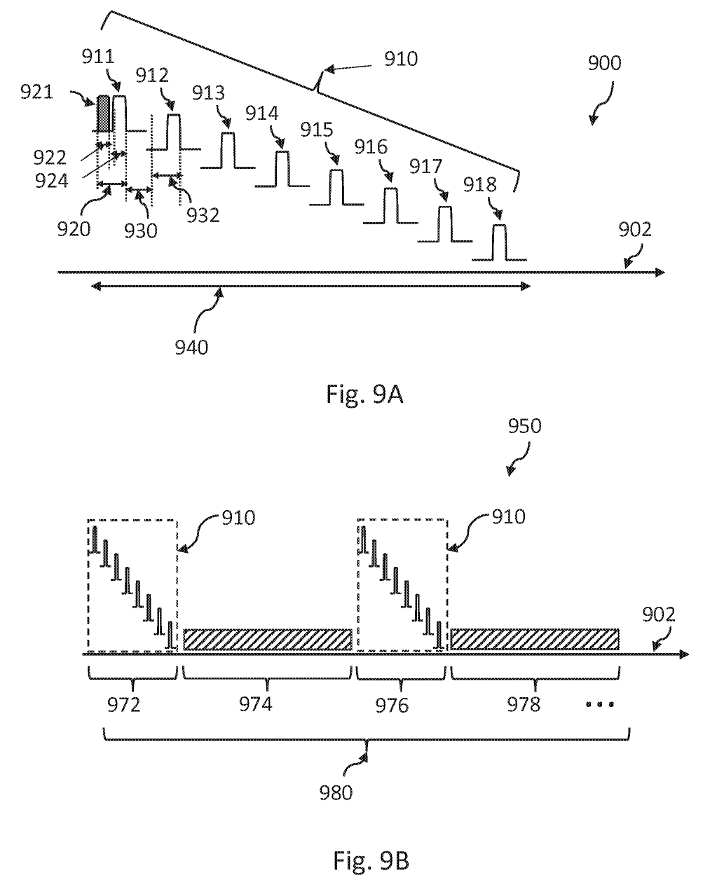

FIG. 9A is a schematic timing diagram 900 showing the relationships among the signal portions of the signals received by the signal processor from the PUTs during a sensing event time frame 940. FIG. 9B is a schematic timing diagram 950 showing the relationships among the sensing event time frames 972, 976 and the signal processing time frames 974, 978 during a touch determination period 980. Each of the sensing time frames 972, 976 (FIG. 9B) may correspond to sensing time frame 940 (FIG. 9A). Timing diagrams 900 and 950 are shown with the x-axis 902 indicating time. The signal timing is explained with reference to the eight PUTs shown at FIGS. 6A and 6B Timing diagram 900 shows signals 910 from the PUTs received at the signal processor 692. Signals 910 comprise the following signal portions (ordered by time sequence): 911 (signal portion from PUT 621), 912 (signal portion from PUT 622), 913 (signal portion from PUT 623), 914 (signal portion from PUT 624), 915 (signal portion from PUT 625), 916 (signal portion from PUT 626), 917 (signal portion from PUT 627), and 918 (signal portion from PUT 628). Each of the signal portions occupies a respective portion of the sensing time frame 940, and there is no overlap of the signal portions in time. Accordingly, these signal portions are in a time-division multiplexed arrangement.

Each of the signal portions (911 – 918) is generated in accordance with the ultrasound waves received at the respective PUTs (621 – 628) during a respective one of the sensing time windows (e.g., sensing time window 920 is shown for signal portion 911). Additional details are described for the example of PUT 621. Sensing time window 920 comprises a first time portion 922 and a second time portion 924 after the first time portion. During first time portion 922, the transmitting-type PUT (e.g., PUT 621 functioning as a transmitting-type PUT) transmits ultrasound waves towards the cover stack 102 in a predetermined frequency range (e.g., in a range of about 0.5 to about 20 MHz), with the ultrasound waves propagating along a normal direction (along z-axis 686) approximately normal to a plane of the one or more piezoelectric members. For example, when a drive voltage signal (e.g., voltage in a range of about 1 to about 50 V, frequency in a range of about 0.5 to about 20 MHz) is applied to the electrodes of a PUT, the PUT may transmit ultrasound waves of approximately the same frequency as the drive voltage along normal direction (along z-axis 686). Such drive voltage signal may be generated by a suitable signal-generation circuit (e.g., circuitry in the signal processor 692 or other circuitry connected to (coupled to) PUT 621). For illustration, the drive voltage signal applied to PUT 621 during the first time portion 922 is schematically shown as 921 in FIG. 9A, although this drive voltage signal is not part of the signals 910 received at the signal processor. The ultrasound waves undergo varying degrees of attenuation depending on objects (if any) in contact with the cover stack 102. A fraction of the ultrasound waves are reflected back towards the PUT(s) (e.g., PUT 621).

During the second time portion 924, the receiving-type PUT (e.g., PUT 621 functioning as a receiving-type PUT) receives the ultrasound waves from the cover stack in the predetermined frequency range. The receiving-type PUT generates time-varying voltage signals in response to the received ultrasound signals. The signal processor (e.g., 692) receives a signal portion (e.g., 911) that is generated in accordance with the ultrasound waves received at the receiving-type PUT (e.g., PUT 621) during a respective sensing time window (e.g., 920). In some implementations, the time-varying voltage signal generated at the receiving-type PUT may undergo amplification, analog-to-digital conversion (ADC), and/or other signal conditioning before it is received at the signal processor as a “signal portion”. In some implementations, a duration of each of the sensing time windows is about 0.1 µs or more, and/or about 1000 µs or less (e.g., in a range of about 0.1 µs to about 1000 µs). There is a second sensing time window 932, associated with a second PUT 622 and second signal portion 912. In the example shown, there is a blank time window 930 between adjacent sensing time windows 920 and 932.

FIG. 9B is a schematic timing diagram 950 showing the relationships among the sensing event time frames 972, 976 and the signal processing time frames 974, 978 during a touch determination period 980. Each of the sensing event time frames 972, 976 (FIG. 9B) may correspond to sensing event time frame 940 (FIG. 9A). A touch determination period may include more than two sensing event time frames. The touch sensor is active at least during the touch determination period (e.g., the touch sensor may also be active during other time periods). In some implementations, a duration of a touch determination period is about 100 ms or more, and/or about 3000 ms or less (e.g., in a range of about 100 ms to about 3000 ms). In some implementations, a duration of a sensing event time frame satisfies one or more of the following: about 100 µs or more, about 200 µs or more, about 10 ms or less, and about 2 ms or less. In some implementations, a duration of a sensing event time frame is in a range of about 100 µs to about 10 ms, about 100 µs to about 2 ms, about 200 µs to about 10 ms, or about 200 µs to about 2 ms. In the example shown, there are signal processing time frames (974, 978) interleaved with the sensing event time frames (e.g., signal processing time frame 974 after sensing event time frame 972 and before sensing event time frame 978. In some implementations, a duration of a signal processing time frame may be in a range of about 1 µs to about 1 ms. The signal processor (e.g., 692) may carry out signal processing during the sensing event time frame and may carry out additional signal processing during the signal processing time frame. In some implementations, signals are received from the PUTs during the sensing event time frames whereas no signals are received from the PUTs during the signal processing time frames. However, other signals (e.g., signals from other sources, such as a wake-up sensor, an external signal source, or another sensor) may be received by the signal processor during the signal processing time frame. In some implementations, an example of another sensor is a piezoelectric force-measuring element (PFE). In some implementations, a piezoelectric capacitor that functions as transmitting-type PUTs and/or receiving-type PUT during a sensing event time frame also functions as a PFE during a signal processing time frame.

During the sensing event time windows (e.g., 972, 976) (and additionally during the signal processing time windows 974, 978, in some implementations), the signal processor determines, from at least the signals (e.g., the signals from the PUTs during the sensing time windows, and optionally additional signals from the PFEs during the signal processing time windows), whether a touch event has occurred (e.g., a finger touch, finger press, finger slide, or another object contacting the cover stack), and at least one other characteristic of the touch event, if the signal processor has determined that the touch event has occurred. Herein, examples of “other characteristics” include touch velocity, touch direction, touch pattern, and touch location. In some cases, determining one of these other characteristics requires a determination of touch location(s). For example, determining a touch velocity may include (1) determining a first location and a first time at which a finger initially touches the outer surface 104 (of the cover stack 102) and starts to slide across the cover stack and (2) determining a second location and a second time (after the first time) at which the finger stops sliding and lifts away from the cover stack. For example, determining a touch pattern includes determining a series of touch locations at which a finger touches the cover stack. Other examples of “other characteristics” include transient applied force and transient strain. Characteristics such as transient strain and transient applied force may be determined in implementations in which the piezoelectric capacitor(s) function as PFE(s) during signal processing time frames. In such implementations, the other characteristics may be determined in accordance with the signals from the PUTs and the additional signals from the PFEs.

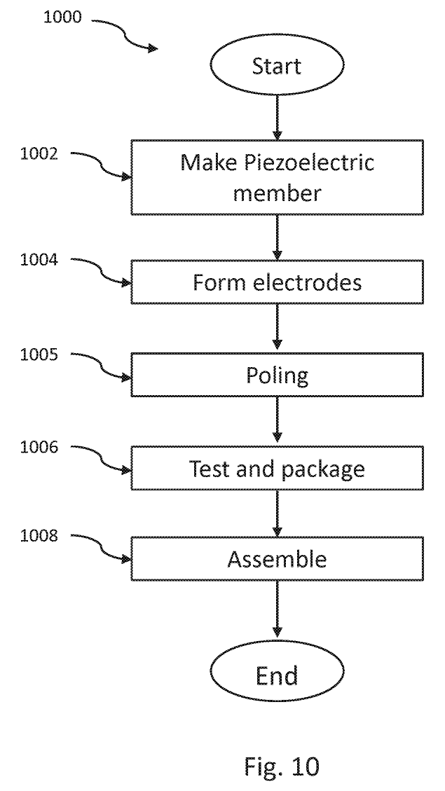

FIG. 10 is a flow diagram of a process 1000 of making a touch sensor device incorporating discrete (e.g., non-micromechanical) piezoelectric capacitors. Process 1000 includes stages 1002, 1004, 1005, 1006, and 1008. At stage 1002, a piezoelectric member is made or provided, to the desired dimensions. As described with reference to FIGS. 4, 5A, and 6A a piezoelectric member may be shared among multiple piezoelectric capacitors, or a respective piezoelectric member may be made or provided for each piezoelectric capacitor. At stage 1004, electrodes are formed on the piezoelectric member(s) to obtain the piezoelectric capacitors. At stage 1005, a poling operation may be carried out: a voltage is applied to the piezoelectric member between the electrodes (e.g., the electrodes formed at stage 1004) to form a built-in piezoelectric polarization. At stage 1006, the piezoelectric capacitors may undergo any necessary testing and packaging. As described with reference to FIGS. 6A and 6B , the necessary packaging may be minimal in some implementations. At stage 1008, the piezoelectric capacitors may undergo final assembly into a larger system, such as mounting (e.g., solder bonding to a circuit board substrate).

FIG. 11A is a schematic plan view of a cover member 1102 (as seen from the exposed outer surface 1106 that may be touched by a finger) of an illustrative opto-electro-mechanical assembly 1100. FIG. 11B is a schematic elevational view of the opto-electro-mechanical assembly 1100. In some examples, the cover member is metallic (e.g., Al or Al alloy) and is electrically conductive (e.g., the cover member may be a metal foil or sheet). In some other examples, the cover member may be a plastic or a ceramic or carbon fibers. The cover member is shown as being flat. In other examples, the cover member may be curved or have a non-flat shape (e.g., curved or stamped metal sheet). The cover member 1102 has perforations (i.e., an aperture in the cover member, also referred to as a cover aperture) 1106 penetrating therethrough, forming visual indicia that may be clearly visible to a user when lit up from behind. The cover members described in other examples may also have perforations (in the example shown, the perforations 1106 form a letter “+”). In the example shown, the visual indicia overlap with a touch sensing region 1104, which is a region that is sensitive to touch when touched or pressed by a finger. The assembly 1100 includes a light-guide plate or sheet (sometimes referred to as a light-guide element) 1110; solid-state light sources (e.g., light-emitting diodes (LEDs)) 1114, 1116; flexible circuit substrates (e.g., flexible printed circuits (FPCs)) 1124, 1126; and a piezoelectric ultrasonic transducer (PUT) 1130. The light emitted from the solid-state light sources 1114, 1116 is input into the light-guide element through respective light-input edges 1115, 1117 of the light-guide element 1110. The light propagates in the light-guide element 1110 and is redirected by a pattern of light-redirecting elements 1118. The light-redirecting elements may comprise, for example, microdots (e.g., printed or otherwise formed on the light-guide element) or microlenses (e.g., formed on or in the light-guide element). At least some of the light redirected by the light-redirecting elements may be extracted from the light-guide element. At least some of the light extracted from the light-guide element 1110 travels toward the cover member 1102. The portion of the light that travels through the perforations 1106 in the cover member 1102 and may be seen by a user located on the side of the outer surface (exposed surface) 1106 of the cover member 1102. Using the illuminated indicia as a guide, a user may perform a touch input action (e.g., a single touch, a single press, multiple presses, a swipe) on the outer surface 1106 that may be sensed using the PUT 1130. The touch sensing region 1104 is the region of the cover member 1102 that corresponds to the lateral extent of the PUT 1130. The cover member 1102 has an outer surface (exposed surface) 1106 and an inner surface 1108 opposite the outer surface. The light-guide element 1110 has a bottom major surface 1111 and a top major surface 1113 opposite the bottom major surface (the top major surface 1113 is closer to the cover member 1102). The top major surface 1113 of the light-guide element is adhered to the inner surface 1108 of the cover member via an adhesive (e.g., adhesive layer) 1112. The light (e.g., light emitted from the solid-state light source) that enters the light-guide element is guided through the light-guide element by reflection at the top major surface 1113 and the bottom major surface 1111, until the light leaks out of the light-guide element or is redirected by the light-redirecting elements. The top major surface 1113 is shown as being flat. However, if the cover member is curved or has a non-flat shape, the top surface may also have a curved or non-flat shape to follow the contours of the cover member. Solid-state light sources 1114, 1116 are mounted to (e.g., mechanically attached to and electrically connected to) respective flexible circuit substrates 1124, 1126. The top surface of PUT 1130 is adhered to the bottom surface 1111 of the light-guide element 1110 via an adhesive (e.g., adhesive layer) 1142. The adhesive 1142 may also function as an acoustic impedance-matching material (e.g., the adhesive may exhibit an acoustic impedance in between those of adjacent materials, i.e., light-guide element and the PUT electrode).hered to the bottom surface 1111 of the light-guide element 1110 via an adhesive (e.g., adhesive layer) 1142. The adhesive 1142 may also function as an acoustic impedance-matching material (e.g., the adhesive may exhibit an acoustic impedance in between those of adjacent materials, i.e., light-guide element and the PUT electrode).

Herein, a material (e.g., adhesive 1142) is said to be acoustic impedance-matching if its acoustic impedance falls between the acoustic impedance values of the adjacent materials that are traversed by the acoustic waves. In some cases, the light-guide element may be a plastic material such as polycarbonate, with an acoustic impedance of around 2.7 x 10⁵ g/(sec cm²) and the PUT electrode may be silver, with an acoustic impedance of around 38 x 10⁵ g/(sec cm²). In such cases, some adhesives, such as cyanoacrylate adhesives (e.g., also referred to as “super glue”) may exhibit an acoustic impedance in between those materials. In some implementations, an acoustic impedance-matching layer may be formed on the top surface of PUT 1130 and/or the bottom surface of the light-guide element 1110, and a separate adhesive layer 1142 may be disposed between PUT 1130 and light-guide element 1110.

PUT 1130 includes a piezoelectric member (e.g., piezoelectric layer, piezoelectric film) 1132 and electrodes on both dies of the piezoelectric member. In the example shown, a first electrode 1134 is formed on a bottom surface of the piezoelectric member. The second electrode 1136 is a “wrap-around” electrode that is formed on a top surface of the piezoelectric member and extends to the bottom surface of the piezoelectric member. The first flexible circuit substrate 1124 is mechanically attached to and electrically connected to the first electrode 1134 and the second flexible circuit substrate 1126 is mechanically attached to and electrically connected to the second electrode 1136. The wrap-around electrode design makes it possible to make an electrical connection to the second electrode 1136 at a portion of the second electrode that is not embedded in the adhesive 1142. Ultrasonic waves transmitted by PUT 1130 propagate through the light-guide element 1110 toward the cover member 1102. Any reflected ultrasonic waves propagate from the cover member 1102 through the light-guide element 1110 towards PUT 1130. Accordingly, light-guide element is configured as a sound-transmitting member in addition to being configured as a light-transmitting member. In the example shown, the light-guide plate is a solid light-transmitting and sound-transmitting member interposed (1) between the solid-state light source(s) and the metallic cover member and (2) between the at least one PUT and the metallic cover member.

In the implementation shown in FIG. 11B, solid-state light sources 1114, 1116 may be side-emitting LEDs that emit sideways into the respective side edges of the light-guide element 1110. In alternative implementations, a front-emitting LED may be employed. Such implementations may be accomplished by providing a PUT with an aperture (e.g., a circular PUT with a circular aperture, a rectangular PUT with a rectangular aperture, a rectangular PUT with a circular aperture, a circular PUT with a rectangular aperture, etc.). Herein, such an aperture in the PUT may be referred to as a PUT aperture. The aperture may be sized to permit light (e.g., from a solid-state light source) to pass through. Alternatively, the aperture may be sized to accommodate a solid-state light source (e.g., front-emitting LED) in the void space thereof. The solid-state light source may be electrically connected to one or more of the circuit substrates (corresponding to 1124, 1126). Accordingly, light emitted by the solid-state light source (positioned below the PUT such that the PUT overlies the solid-state light source, or positioned in the void space of the PUT aperture) reaches and passes through the solid light-transmitting and sound-transmitting member before reaching the cover member, thereby illuminating the cover aperture. The solid light-transmitting and sound-transmitting member may include a pattern of light-redirecting elements to diffuse the light before the light reaches the cover aperture.

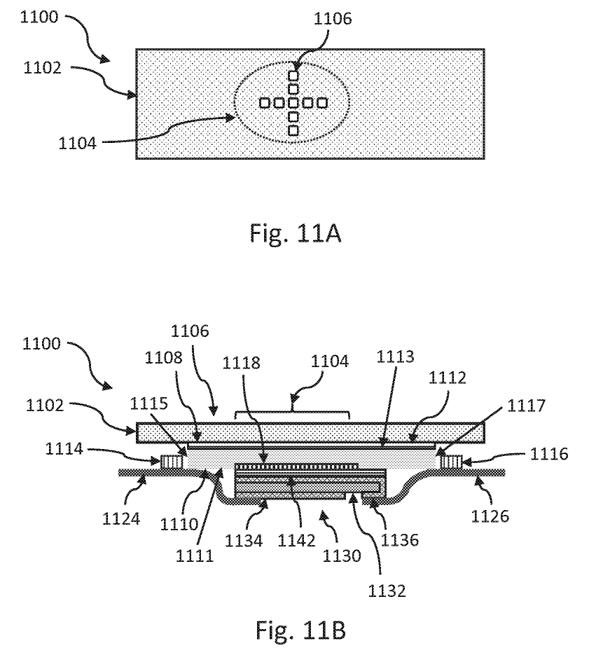

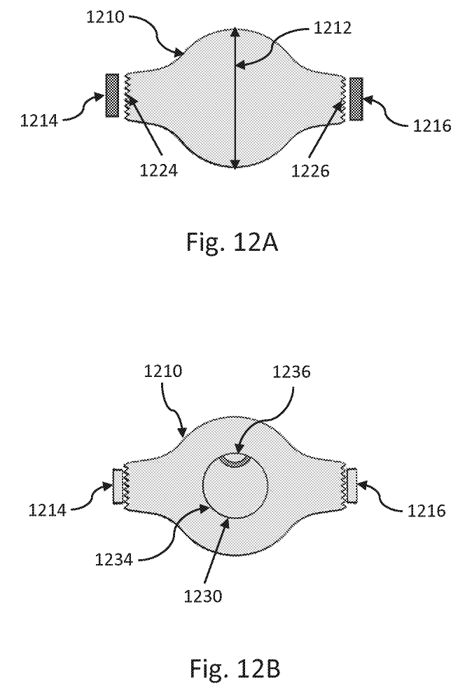

FIG. 12A is a schematic plan view an example light-guide element 1210 as seen from a first side. In the example shown, solid-state light sources 1214, 1216 are positioned to input light into the light-guide element 1210 via respective light-input edges 1224, 1226. Each of the light-input edges includes a pattern of refractive elements (e.g., lenticular elements) to spread the light as it enters the light-guide element 1210. The width of the light-guide element 1210 is greatest approximately mid-way between the two light-input edges (greatest width shown as 1212). As the light propagates in the light-guide element 1210, the lateral extent of the light increases. The light is extracted from the light-guide element by a pattern of light-redirecting elements (located at the bottom of the light-guide element, not shown in FIG. 12A); the extracted light is extracted towards the top surface of the light-guide element (e.g., out of the page towards the reader).

FIG. 12B is a schematic plan view the example light-guide element 1210 as seen from a second side opposite the first side. When seen from the second side, there is also a PUT 1230 that has been attached to the light-guide element 1210. PUT 1230 includes a first electrode 1234 and a second electrode 1236. The second electrode 1236 may be of a wrap-around design.

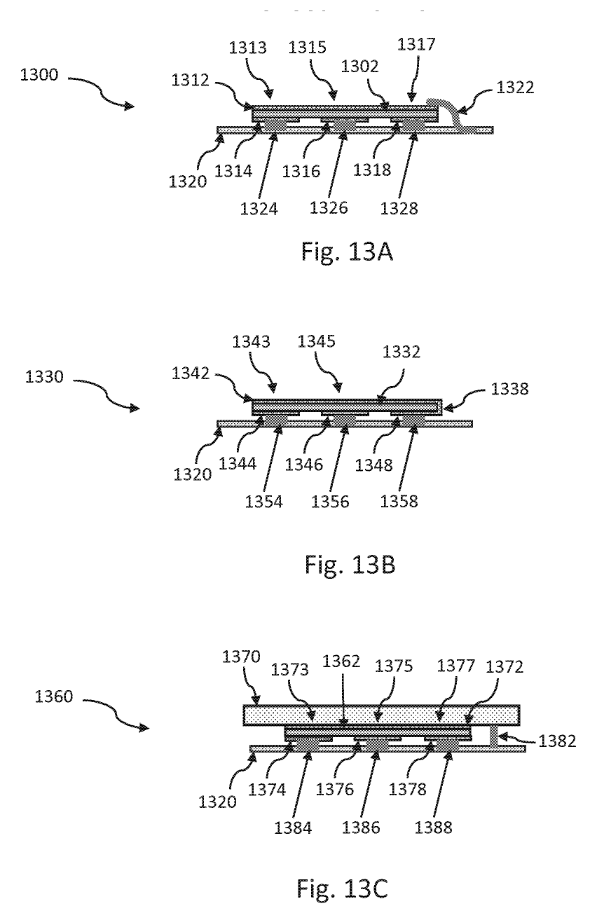

FIGS. 13A, 13B and 13C, are schematic elevational views of respective sensor assemblies. These figures illustrate some examples of arrangements of piezoelectric transducers and underlying circuit substrates. FIG. 13A shows a sensor assembly 1300, which includes an array of piezoelectric transducers (piezoelectric transducers 1313, 1315, 1317). These piezoelectric transducers share a common piezoelectric member 1302 and a common top electrode 1312. Each of the piezoelectric transducers 1313, 1315, 1317 includes a respective bottom electrode 1314 ,1316, 1318. Each of the bottom electrodes 1314, 1316, 1318 is mounted to (e.g., mechanically attached to and electrically connected to) a circuit substrate (e.g., printed circuit board (PCB)) 1320 via a respective connection (e.g., solder bump, ACF (anisotropic conductive film) connection) 1324, 1326, 1328. Top electrode 1302 is connected to circuit substrate 1320 via a flexible interconnection (e.g., flexible printed circuit (FPC)) 1322. In some implementations, top electrode 1312 is configured as a ground electrode (GND). Several different implementations are possible: (1) all piezoelectric transducers are PUTs (e.g., piezoelectric transducers 1313, 1315, 1317 are PUTs), (2) at least one of the piezoelectric transducers is a PUT and at least one of the other piezoelectric transducers is a PFE (e.g., piezoelectric transducers 1313, 1317 are PFEs and piezoelectric transducer 1315 is a PUT), and (3) at least one of the piezoelectric transducers is configured as a PUT and as a PFE (e.g., piezoelectric transducer 1315 is configured as a PUT and as a PFE).

FIG. 13B shows a sensor assembly 1330, which includes an array of piezoelectric transducers (piezoelectric transducers 1343, 1345). These piezoelectric transducers share a common piezoelectric member 1332 and a common top electrode 1342. Each of the piezoelectric transducers 1343, 1345 includes a respective bottom electrode 1344, 1346. Top electrode 1342 wraps around the right side 1338 of the piezoelectric member 1332 and connects to a bottom electrode 1348. Each of the bottom electrodes 1344, 1346, 1348 is mounted to (e.g., mechanically attached to and electrically connected to) circuit substrate (e.g., printed circuit board (PCB)) 1320 via a respective connection (e.g., solder bump, ACF (anisotropic conductive film) connection) 1354, 1356, 1358. In some implementations, top electrode 1342 is configured as a ground electrode (GND). Several different implementations are possible: (1) all piezoelectric transducers are PUTs (e.g., piezoelectric transducers 1343, 1345 are PUTs), (2) at least one of the piezoelectric transducers is a PUT and at least one of the other piezoelectric transducers is a PFE (e.g., piezoelectric transducer 1343 is a PFE and piezoelectric transducer 1345 is a PUT), and (3) at least one of the piezoelectric transducers is configured as a PUT and as a PFE (e.g., piezoelectric transducer 1343 and/or 1345 is configured as a PUT and as a PFE).

FIG. 13C shows a sensor assembly 1360, which includes an array of piezoelectric transducers (piezoelectric transducers 1373, 1375, 1377). These piezoelectric transducers share a common piezoelectric member 1362 and a common top electrode 1372. Each of the piezoelectric transducers 1373, 1375, 1377 includes a respective bottom electrode 1374, 1376, 1378. Each of the bottom electrodes 1374, 1376, 1378 is mounted to (e.g., mechanically attached to and electrically connected to) circuit substrate (e.g., printed circuit board (PCB)) 1320 via a respective connection (e.g., solder bump, ACF (anisotropic conductive film) connection) 1384, 1386, 1388. In some implementations, top electrode 1372 is configured as a ground electrode (GND). The top electrode 1372 is attached to (electrically connected to) a metal backing substrate 1370 which is electrically connected to a wiring in the circuit substrate 1320 via an interconnection 1382. Several different implementations are possible: (1) all piezoelectric transducers are PUTs (e.g., piezoelectric transducers 1373, 1375, 1377 are PUTs), (2) at least one of the piezoelectric transducers is a PUT and at least one of the other piezoelectric transducers is a PFE (e.g., piezoelectric transducer 1373 is a PFE and piezoelectric transducers 1375, 1377 are PUTs), and (3) at least one of the piezoelectric transducers is configured as a PUT and as a PFE (e.g., piezoelectric transducer 1375 is configured as a PUT and as a PFE).

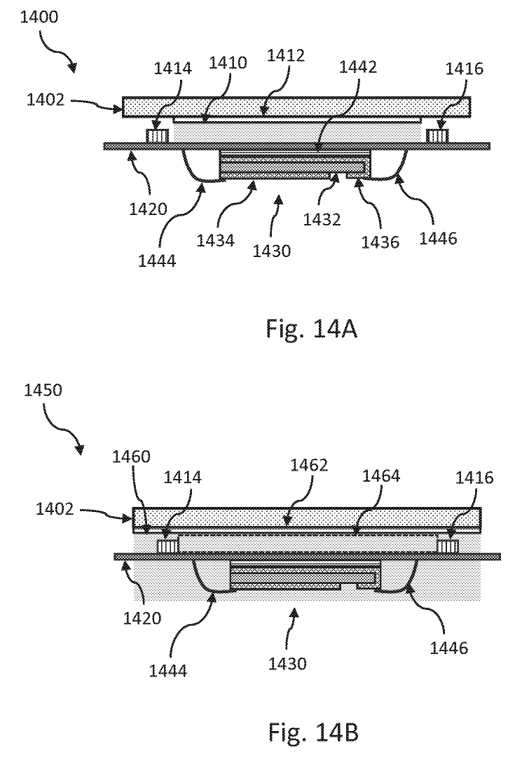

FIGS. 14A and 14B are schematic elevational views of respective opto-electro-mechanical assemblies. FIG. 14A shows an opto-electro-mechanical assembly 1400, which includes a cover member (e.g., metallic cover member) 1402; a light-guide element 1410; solid-state light sources (e.g., light-emitting diodes (LEDs)) 1414, 1416; a circuit substrate (e.g., a PCB) 1420; and a piezoelectric ultrasonic transducer (PUT) 1430. The light emitted from the solid-state light sources 1414, 1416 is input into and propagate in the light-guide element and is extracted from the light-guide element towards cover member 1402. The light that travels through the cover member (e.g., an aperture in the cover member or cover aperture) may be visible to a user. The light-guide element 1410 and the cover member 1402 are adhered to each other via an adhesive 1412. In some implementations, the adhesive may also function as an acoustic impedance-matching layer or a separate acoustic impedance-matching layer may be present. Solid-state light sources 1414, 1416 and light-guide element 1410 are mounted to the circuit substrate 1420 at its top surface. PUT 1430 includes a piezoelectric member 1432, a bottom electrode 1434, and a top electrode 1436 (of a wrap-around configuration). PUT is mounted to the circuit substrate 1420 at its bottom surface. PUT 1430 and circuit substrate 1420 are adhered to each other via an adhesive 1442. In some implementations, the adhesive may also function as an acoustic impedance-matching layer or a separate acoustic impedance-matching layer may be present. Wiring connections 1444, 1446 connect bottom electrode 1434 and top electrode 1436, respectively, to circuit substrate 1420. Light-guide element 1410 also transmits ultrasonic waves (e.g., ultrasonic waves traveling upward from PUT 1430, reflected ultrasonic waves traveling downward from cover member 1402).

FIG. 14B shows an opto-electro-mechanical assembly 1450, which is similar to opto-electro-mechanical assembly 1400 in some respects. Opto-electro-mechanical assembly 1450 includes cover member 1402; solid-state light sources 1414, 1416; circuit substrate 1420; PUT 1430; and wiring connections 1444, 1446 are as described for opto-electro-mechanical assembly 1400. In the example shown, components such as solid-state light sources 1414, 1416, PUT 1430, and wiring connections 1444, 1446, and a portion of circuit substrate 1420, are embedded in a solid member (e.g., overmolding material) 1460 which is light-transmitting and sound-transmitting. A portion 1464 of the solid member 1460 between the solid-state light sources 1414, 1416 functions as a light-guide element. Solid member 1460 also transmits ultrasonic waves (e.g., ultrasonic waves traveling upward from PUT 1430, reflected ultrasonic waves traveling downward from cover member 1402). Solid member 1460 is adhered to cover member 1402 via an adhesive 1462. In some implementations, the adhesive may also function as an acoustic impedance-matching layer or a separate acoustic impedance-matching layer may be present.

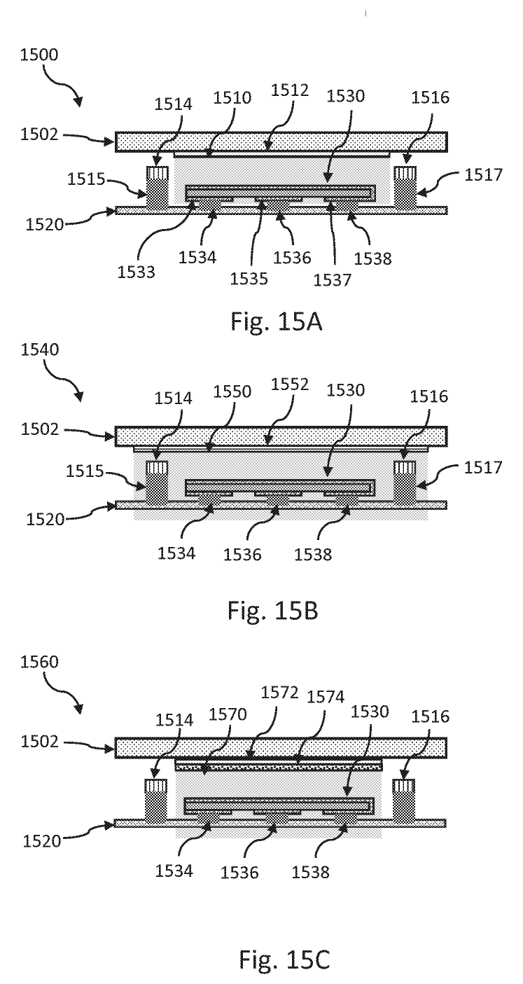

FIGS. 15A, 15B, and 15C, are schematic elevational views of respective opto-electro-mechanical assemblies. FIG. 15A shows an opto-electro-mechanical assembly 1500, which includes a cover member 1502; solid-state light sources 1514, 1516; circuit substrate 1520; PUT 1530; and a solid light-transmitting and sound-transmitting member 1510. Solid-state light sources 1514, 1516 are mounted to circuit substrate 1520 via respective conductive interposers 1515, 1517. PUT 1530 is mounted to circuit substrate 1520 via electrical connections (e.g., solder bumps, ACF (anisotropic conductive film) connections) 1534, 1536, 1538. PUT 1530 is encapsulated in a solid member 1510 which transmits light (e.g., light input into the light-guide element from the solid-state light sources) and sound (e.g., ultrasonic waves emitted by the PUT, reflected ultrasonic waves from the cover member). Solid member 1510 and cover member 1502 are adhered to each other via an adhesive 1512. In some implementations, the adhesive may also function as an acoustic impedance-matching layer or a separate acoustic impedance-matching layer may be present. A possible manufacturing process for the solid member 1510 includes (1) providing PUT 1530, (2) encapsulating PUT 1530 in a molding material and forming into a shape of the solid member, (3) exposing the bottom electrodes 1533, 1535, 1537 of PUT 1530 (e.g., by an etching process), and (4) mounting the solid member onto the circuit substrate 1520 via a respective electrical connection 1534, 1536, 1538 for each of the exposed electrodes 1533, 1535, 1537.

FIG. 15B shows an opto-electro-mechanical assembly 1540 which is similar to opto-electro-mechanical assembly 1500 in some respects. Opto-electro-mechanical assembly 1540 includes a solid member (light-transmitting and sound-transmitting) 1550 which encapsulates the components (e.g., solid-state light sources 1514, 1516, conductive interposers 1515, 1517, PUT 1530 including the electrical connections 1534, 1536, 1538) after the components have been mounted to circuit substrate 1520. A portion of circuit substrate 1520 is also encapsulated in the solid member 1550. Solid member 1550 and cover member 1502 are adhered to each other via an adhesive 1552. In some implementations, the adhesive may also function as an acoustic impedance-matching layer or a separate acoustic impedance-matching layer may be present. A possible manufacturing process for the solid member 1550 includes (1) mounting PUT 1530, via electrical connections, to circuit substrate 1520, (2) mounting solid-state light sources 1514, 1516, via conductive interposers, to circuit substrate 1520, and (3) encapsulating PUT 1530, solid-state light sources 1514, 1516, and a portion of circuit substrate 1520, in a molding material and forming into a shape of the solid member.

FIG. 15C shows an opto-electro-mechanical assembly 1560 which is similar to opto-electro-mechanical assemblies 1500, 1540 in some respects. Opto-electro-mechanical assembly 1560 includes a solid member (light-transmitting and sound-transmitting) 1570 which encapsulates PUT 1530 (including the electrical connections 1534, 1536, 1538 after it has been mounted to circuit substrate 1520). A portion of circuit substrate 1520 is also encapsulated in the solid member 1570. Solid-state light sources 1514, 1516 are not encapsulated in solid member 1570. A possible manufacturing process for the solid member 1570 includes (1) mounting PUT 1530, via electrical connections, to circuit substrate 1520, and (2) encapsulating PUT 1530, and a portion of circuit substrate 1520, in a molding material and forming into a shape of the solid member. Solid member 1570 has an acoustic impedance-matching layer 1574 at its top surface. Solid member 1570 (including the impedance-matching layer 1574 formed on or adhered to its top surface) and cover member 1502 are adhered to each other via an adhesive 1572.

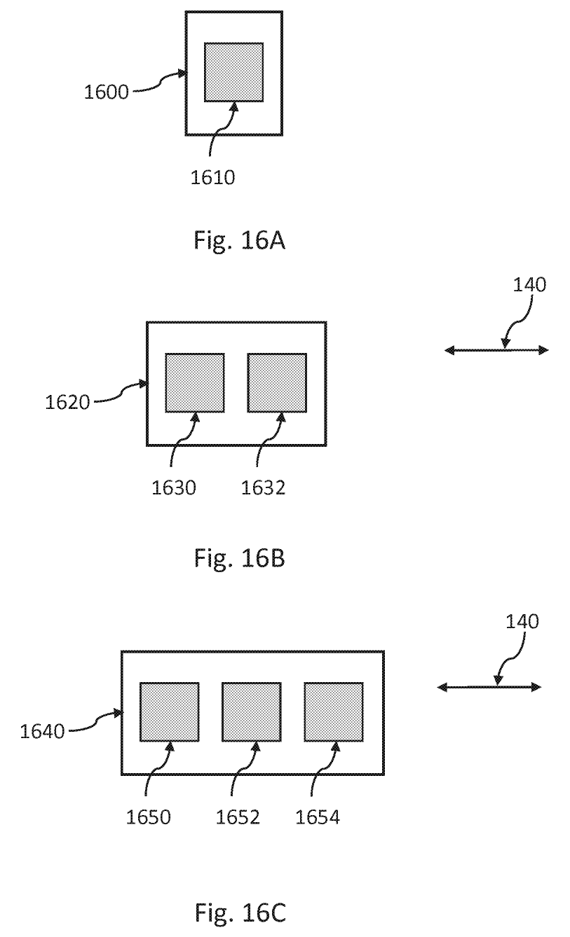

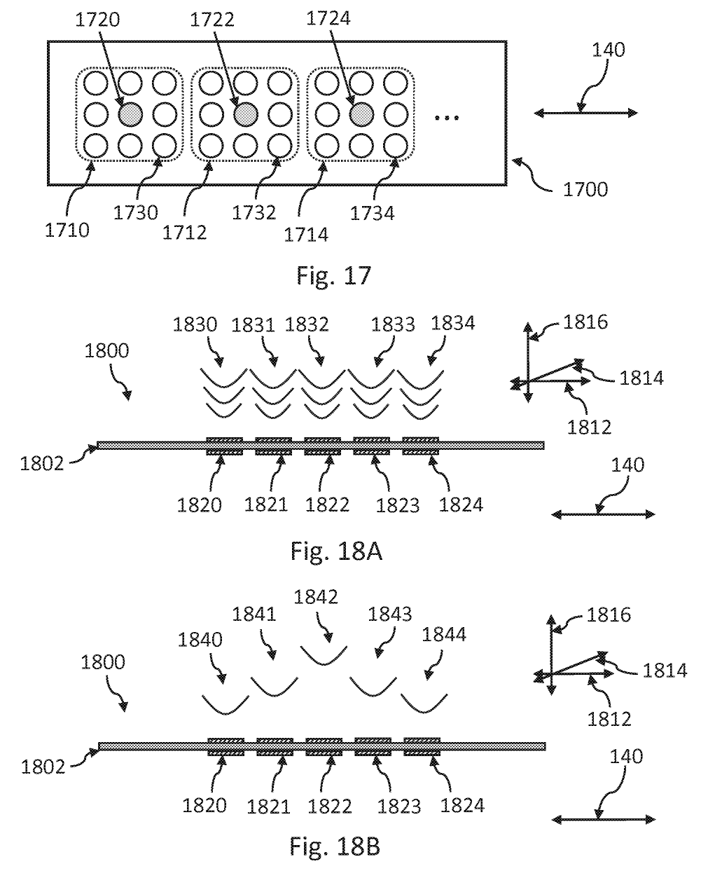

FIG. 16A is a schematic plan view of a sensor assembly 1600 including a single touch-sensing element 1610. For example, the touch-sensing element is configured as a piezoelectric ultrasonic transducer (PUT). The PUT may be in both a transmit mode and a receive mode (e.g., transmitting ultrasound waves toward a cover member at certain times, receiving reflected ultrasound waves traveling toward the PUT at other times). FIG. 16B is a schematic plan view of a sensor assembly 1620 including an array, extending along a longitudinal direction 140, of touch-sensing elements 1630, 1632. For example, the touch-sensing elements are configured as PUTs. In some examples, PUT 1630 may be in a transmit mode and PUT 1632 may be in a receive mode. FIG. 16C is a schematic plan view of a sensor assembly 1640 including an array, extending along a longitudinal direction 140, of touch-sensing elements 1650, 1652, and 1654. For example, the touch-sensing elements are configured as PUTs. In some examples, the PUTs at the left and right edges (1650, 1654) may be in a transmit mode and the PUT in the center (1652) may be in a receive mode. Such a configuration in which multiple PUTs transmit ultrasound waves can be used to conduct beam-forming of the transmitted ultrasound waves, as explained in greater detail with reference to FIGS. 17, 18A, and 18B, .

FIG. 17 is a schematic plan view of an array 1700 of PUTs including transmitting-type PUTs and receiving-type PUTs. The array 1700 extends along a longitudinal direction 140. In the example shown, there are three touch-sensing elements (e.g., 1710, 1712, 1714). Touch-sensing element (1710, 1712, 1714) includes transmitting-type PUTs (e.g., 1730, 1732, 1734) (indicated as white circles, there are 8 transmitting-type PUTs for each touch-sensing element) and a receiving-type PUT (e.g., 1720, 1722, 1724) (grey circles). In the example shown, each of the PUTs is either a transmitting-type PUT, or a receiving-type PUT, but not both types. In the example shown, the transmitting-type PUTs surround a receiving-type PUT in the middle. Furthermore, the PUTs are shown as being approximately circular or approximately round whereas in other examples, PUTs (e.g., FIGS. 2,3,5B, ) are shown as being approximately rectangular or approximately square. One advantage of the arrangement of FIG. 17 in which there are more transmitting-type PUTs than receiving-type PUTs (e.g., in the example shown, a ratio of transmitting-type PUTs to receiving-type PUTs is 8:1, with the PUTs being about the same in area) is that the power of the transmitting ultrasound waves may be increased. In some implementations, the power enhancement may be attained when the ultrasound waves transmitted by the transmitting-type PUTs interfere constructively.

FIG. 18A is a schematic elevational view of a sensor assembly 1800 comprising a piezoelectric member 1802 and PUTs 1820 – 1824 at respective locations along the piezoelectric member 1802. The PUTs are arrayed along the longitudinal direction 140. The plane of the piezoelectric member is approximately parallel to the plane formed by the x-axis 1812 and the y-axis 1814. FIG. 18A schematically shows respective example waveforms (1830 – 1834) transmitted by each of the PUTs (1820 – 1824). These transmitted waveforms propagate along the normal direction (direction of the z-axis 1816, direction approximately normal to the plane of the piezoelectric member). In the example shown (FIG. 18A), the ultrasound waves transmitted from each of the PUTs are independent of the ultrasound waves transmitted by other ones of the PUTs. Accordingly, there is no constructive interference in the example of FIG. 18A. The ultrasound waves expand laterally as they travel further away from the transmitting PUT. FIG. 18B shows the same sensor assembly 1800 as in FIG. 18A. FIG. 18B schematically shows respective example waveforms (1840 – 1844) transmitted by each of the PUTs (1820 – 1824). In the example shown (FIG. 18B), the waveform 1842 at the center (transmitted by central PUT 1822) is followed, with a predetermined phase delay, by waveforms 1841, 1843 outside of the center (transmitted by PUTs 1821, 1823), which in turn are followed, with a predetermined phase delay, by waveforms 1840, 1844 further outside of center (transmitted by PUTs 1820, 1824). These ultrasound waves interfere constructively and form a beam that converges near a point above the central PUT 1822 (e.g., a point above the central PUT 1822 at the outside surface of the cover stack, when the cover stack and the sensor assembly are assembled together and mechanically coupled to each other). This is an example of beam-forming, in which ultrasound waves transmitted from multiple PUTs are constructively interfered to form a unified wavefront. Accordingly, in this manner, waveforms with relatively narrow beamwidths may be obtained. In some implementations, the ultrasound waves transmitted by the transmitting-type PUTs have a beamwidth in a range of 100 µm to 10 mm at the outer surface of the cover stack. In some implementations, the lateral dimensions of the PUTs (piezoelectric capacitors) are in a range of about 100 µm to about 10 mm, and the beamwidths are comparable to these lateral dimensions.

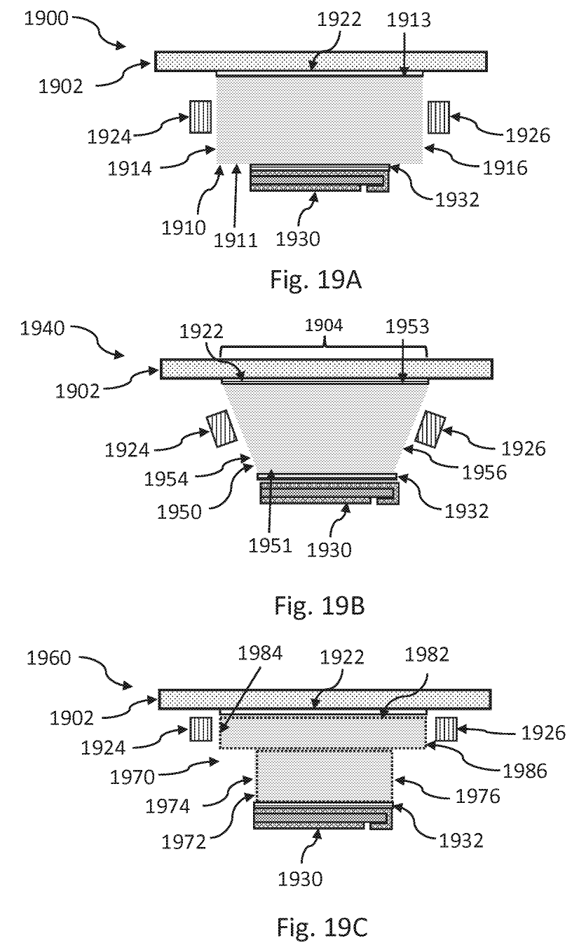

FIGS. 19A, 19B, and 19C, are schematic elevational views of respective opto-electro-mechanical assemblies. FIG. 19A shows an opto-electro-mechanical assembly 1900, including a cover member 1902, solid-state light sources 1924, 1926, a solid member (light-transmitting and sound-transmitting) 1910, and a PUT 1930. Solid-state light sources 1924, 1926, are configured to input light into the solid member 1910 via respective light input surfaces 1914, 1916 of the solid member. Solid member 1910 has a top surface 1913 at which the solid member and the cover member are adhered, via an adhesive 1922. Solid member 1910 has a bottom surface 1911 at which the solid member and PUT 1930 are adhered, via an adhesive 1932. In some implementations, the adhesive (1922 and/or 1932) may also function as an acoustic impedance-matching layer or a separate acoustic impedance-matching layer may be present. As shown in FIG. 19A, the cross-sectional shape of the solid member 1910 is approximately rectangular (e.g., adjacent pairs of surfaces 1911, 1914, 1913, 1916 are approximately perpendicular to each other, opposing pairs of surfaces 1911, 1913 and 1914, 1916 are approximately parallel to each other).

FIG. 19B shows an opto-electro-mechanical assembly 1940, which is similar to opto-electro-mechanical assembly 1900 in some respects. Opto-electro-mechanical assembly 1940 includes a solid member (light-transmitting and sound-transmitting) 1950 which has a top surface 1953, a light-input surface 1954 (into which light emitted by solid-state light source 1924 is input), a light-input surface 1956 (into which light emitted by solid-state light source 1926 is input), and a bottom surface 1951. As shown in FIG. 19B, the cross-sectional shape of the solid member 1950 is approximately trapezoidal (e.g., top surface 1953 and bottom surface 1951 are approximately parallel; light-input surfaces 1954, 1956 are not parallel to each other). This trapezoidal shape is widest near the top surface 1953 and narrowest near the bottom surface 1951. Accordingly, the reflected ultrasound waves traveling through solid member 1950 towards PUT 1930 from the cover member 1902 diminish in lateral extent (e.g., along 1951, 1953). In particular, the width of the bottom surface 1951 is about the same width as that of PUT 1930. This configuration may increase the probability that the reflected ultrasound waves are incident on PUT 1930. Compare this to the configuration of solid member 1910 (FIG. 19A) in which some of the reflected ultrasound waves may be incident on exposed portions of the bottom surface 1911 that are not covered by PUT 1930 via adhesive 1932. In some implementations, the configuration of 1950 (as compared to 1910) may enhance the signal-to-noise (S/N) ratio of the ultrasound waves detected by PUT 1930. The touch-sensing region 1904 corresponds approximately to the extent of the ultrasound waves at the cover member; hence, by adopting this trapezoidal cross section, a touch-sensing region with a lateral extent much greater than that of PUT 1930 may be realized. In addition, because of the orientation of the solid-state light sources 1924, 1926 towards the cover member, this trapezoidal light-guide element shape may more efficiently illuminate visual indicia located near the center of the cover member.

FIG. 19C shows an opto-electro-mechanical assembly 1960, which is similar to opto-electro-mechanical assemblies 1900, 1940 in some respects. Opto-electro-mechanical assembly 1960 includes a solid member (light-transmitting and sound-transmitting) 1970 which includes a top portion 1982 (with a rectangular cross section) and a bottom portion 1972 (with a rectangular cross section narrower than that of 1982). Solid-state light sources 1924, 1926 input light into top portion 1982 via respective light-input surfaces 1984, 1986. Bottom portion 1972 has side walls 1974, 1976. In particular, the width (e.g., distance between 1974 and 1976) of the bottom portion 1972 is about the same width as that of PUT 1930.

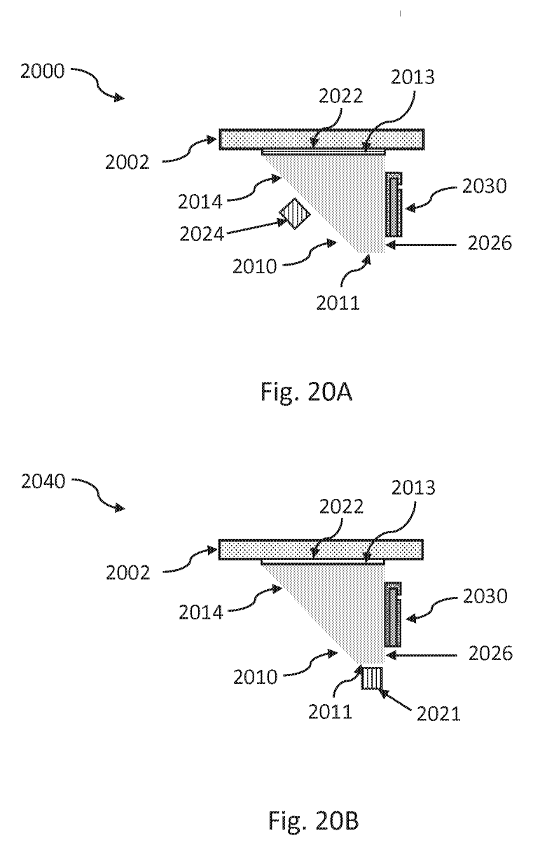

FIGS. 20A and 20B are schematic elevational views of respective opto-electro-mechanical assemblies. In the opto-electro-mechanical assemblies shown in FIGS. 11B, 14B, 15A, 15B, 15C, 19A, 19B, and 19C, the respective PUTs are configured to emit ultrasound waves directly toward the respective cover member, via at least the respective light-transmitting and sound-transmitting solid member. In addition, the emitted ultrasound waves may also travel through other components such as adhesives (e.g., adhesive between the PUT and solid member, adhesive between the solid member and cover member). FIG. 20A shows an opto-electro-mechanical assembly 2000 including a cover member 2002, solid-state light source 2024, a solid member (light-transmitting and sound-transmitting) 2010, and a PUT 2030. Solid-state light source 2024 is configured to input light into the solid member 2010 via side wall (light-input surface) 2014 of the solid member. Solid member 2010 has a top surface 2013 at which the solid member and the cover member are adhered, via an adhesive 2022. In some implementations, the adhesive may also function as an acoustic impedance-matching layer or a separate acoustic impedance-matching layer may be present. Solid member 2010 has a side surface 2026 at which the solid member and PUT 2030 are adhered, via an adhesive (not shown). In some implementations, the adhesive may also function as an acoustic impedance-matching layer or a separate acoustic impedance-matching layer may be present. As shown in FIG. 20A, the cross-sectional shape of the solid member 2010 is approximately trapezoidal (e.g., top surface 2013 and bottom surface 2011 are approximately parallel; side walls 2014, 2026 are not parallel to each other). Side wall 2014 is the light-input surface (for solid-state light source 2024) and side wall 2026 is a sound-input surface (for PUT 2030). This trapezoidal shape is widest near the top surface 2013 and narrowest near the bottom surface 2011. Side wall 2026 is approximately perpendicular to the top surface 2013 and bottom surface 2011. Side wall 2014 is at an acute angle relative to the top surface and at an obtuse angle relative to the bottom surface. PUT 2030 is oriented such that ultrasound waves emitted by PUT 2030 are input into the solid member 2010 (via side wall 2026), are reflected at side wall 2014, and are redirected toward the cover member. The PUT is oriented such that its ultrasound waves are reflected at at least one surface of the solid member before reaching the cover member, including the cover aperture. These ultrasound waves undergo absorption and reflection at the cover member (e.g., at the outer surface of the cover member which may be touched by a finger). The reflected ultrasound waves (i.e., ultrasound waves reflected at the cover member) undergo an additional reflection at side wall 2014 before reaching PUT 2030.

FIG. 20B shows an opto-electro-mechanical assembly 2040, which is similar to opto-electro-mechanical assemblies 2000 in some respects. Opto-electro-mechanical assembly 2040 includes a solid-state light source 2021, configured to input light into the solid member 2010 via the bottom surface 2011 (instead of via slanted side wall 2014). Accordingly, light from solid-state light source directly illuminates the top surface 2013. Ultrasound waves emitted by PUT 2030 are reflected at side wall 2014 before being redirected toward the cover member.

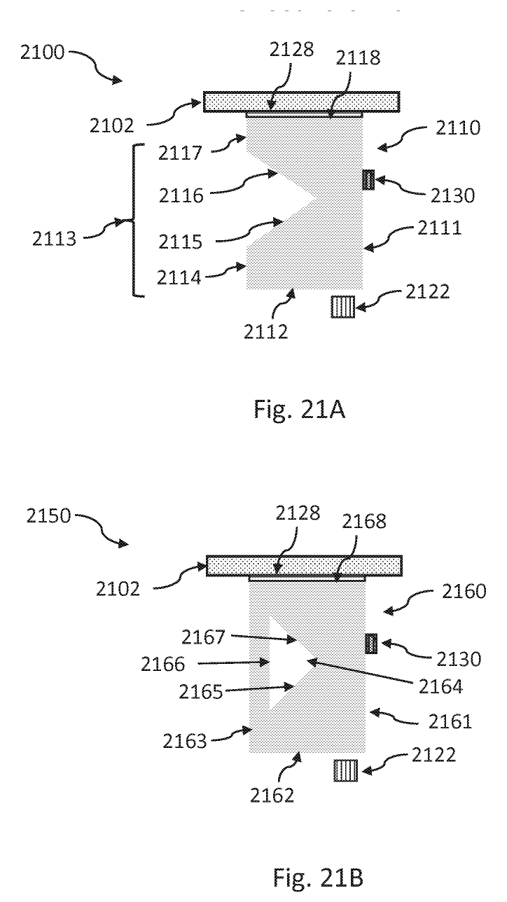

FIGS. 21A and 21B are schematic elevational views of respective opto-electro-mechanical assemblies. FIG. 21A shows an opto-electro-mechanical assembly 2100 including a cover member 2102, solid-state light source 2122, a solid member (light-transmitting and sound-transmitting) 2110, and a PUT 2130. Solid member 2110 has multiple surfaces, including top surface 2118, bottom surface 2112, right side wall 2111, and a left side wall 2113. Solid-state light source 2122 is configured to input light into the solid member 2110 via bottom surface 2112 of the solid member. Accordingly, light from solid-state light source directly illuminates the top surface 2118. Solid member 2110 is adhered to cover member 2102 at its top surface 2118 via an adhesive 2128. In some implementations, the adhesive may also function as an acoustic impedance-matching layer or a separate acoustic impedance-matching layer may be present. Left side wall 2113 includes side wall portions 2114, 2115, 2116, 2117, with side wall portions 2115, 2116 forming a V-shaped groove extending inward into the solid member 2110. PUT 2130 is oriented and positioned such that ultrasound waves emitted by PUT 2130 is reflected at a surface of the V-groove (e.g., side wall portion 2116) before reaching the cover member. The V-shaped groove (2115, 2116) may be shaped and configured as a lenticular element to spread and diffuse the light from the solid-state light source 2122.

FIG. 21B shows an opto-electro-mechanical assembly 2150, which is similar to opto-electro-mechanical assemblies 2100 in some respects. Opto-electro-mechanical assembly 2150 includes a solid member 2160. Solid member 2160 has right side wall 2161, left side wall 2163, a top surface 2168, and a bottom surface 2162. Solid member 2160 also includes an interior hollow region 2164 that forms air-solid interfaces (e.g., 2165, 2166, 2167). Ultrasound waves emitted by PUT 2130 are reflected at air-solid interface 2167 before being redirected toward the cover member. The hollow region (2164) may be shaped and configured as a lenticular element to spread and diffuse the light from the solid-state light source 2122.

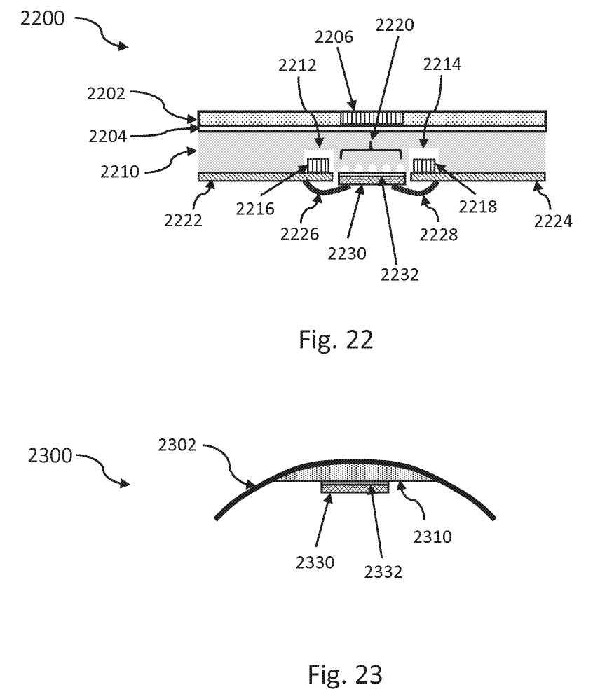

FIG. 22 is a schematic elevational view of an opto-electro-mechanical assembly. FIG. 22 shows an opto-electro-mechanical assembly 2200, which includes a cover member (e.g., metallic cover member) 2202; a light-guide element 2210; solid-state light sources (e.g., light-emitting diodes (LEDs)) 2216, 2218; circuit substrates (e.g., printed circuit board (PCB), flexible printed circuit board (FPC)) 2222, 2224; and a piezoelectric ultrasonic transducer (PUT) 2230. The solid-state light sources 2216, 2218 are housed in respective cavities 2212, 2214, formed in the light-guide element 2210 and are electrically connected to respective circuit substrates 2222, 2224. In some examples, the metallic cover member 2202 may be a 0.8 mm thick perforated metal (e.g., stainless steel, aluminum). The metallic cover member 2202 and the light-guide element 2210 are adhered to each other by an adhesive layer 2204. In some examples, the adhesive 2204 may be a hot-melt adhesive. A pattern of light-redirecting elements 2220 is located on the bottom surface of the light-guide element, in between the cavities 2212, 2214. In the example shown, the light-redirecting elements are microlenses. PUT 2230 is electrically connected to the circuit substrates 2222, 2224 via respective wiring connections 2226, 2228. PUT 2230 is adhered to the light-guide element by an adhesive layer 2232. In some examples, the adhesive 2232 may be a cyanoacrylate adhesive (“super glue”) and may also function as an acoustic impedance-matching layer with an acoustic impedance that is in between those of the PUT electrode and the light-guide element 2210. The pattern of light-redirecting elements 2220 overlies PUT 2230. The light emitted from the solid-state light sources 2216, 2218 is input into and propagate in the light-guide element and is extracted from the light-guide element towards cover member 2202. The light that travels through the cover aperture 2206 may be visible to a user.

FIG. 23 is a schematic elevational view of an opto-electro-mechanical assembly. FIG. 23 shows an opto-electro-mechanical assembly 2300, which includes a cover member (e.g., metallic cover member) 2302; a solid light-transmitting and sound-transmitting member (e.g., light-guide element) 2310; and a piezoelectric ultrasonic transducer (PUT) 2330. Solid light-transmitting and sound-transmitting member 2310 and PUT 2330 are adhered to each other by an adhesive layer 2332. A solid-state light source is present in the opto-electro-mechanical assembly 2300 but is not shown in the cross-sectional view of FIG. 23. Notably, the cover member is curved, and the solid light-transmitting and sound-transmitting member has a curved contour that follows the shape of the cover member. In other implementations, the PUT may be embedded in the solid light-transmitting and sound-transmitting member (e.g., made in an overmolding process).

Additional information about piezoelectric ultrasonic transducers micromechanical force-measuring elements (PMFEs) and piezoelectric micromechanical ultrasonic transducers (PMUTs) can be found in U.S. Patent Application Publication Nos. US 2021/0181041 A1 and US 2021/0242393 A1. Additional information about discrete piezoelectric capacitors generally (including piezoelectric ultrasonic transducers) may be found in U.S. Patent Application Publication No. 2021/0242393 A1.

From the foregoing, it will be appreciated that specific embodiments of the invention have been described herein for purposes of illustration, but that various modifications may be made without deviating from the scope of the invention. Accordingly, the invention is not limited except as by the appended claims.

We claim:

1. An opto-electro-mechanical assembly, comprising:
a metallic cover member having an outer surface that can be touched by a finger;
a solid-state light source;
at least one piezoelectric ultrasonic transducer (PUT) comprising a piezoelectric layer;
a solid light-transmitting and sound-transmitting member interposed (1) between the solid-state light source and the metallic cover member and (2) between the at least one PUT and the metallic cover member; and
a circuit substrate to which the solid-state light source and the at least one PUT are electrically connected,
wherein:
the metallic cover member has a cover aperture that transmits light emitted from the solid-state light source toward the outer surface.

2. A touch-sensing system, comprising:
the opto-electro-mechanical assembly of claim 1; and
a processor coupled to the opto-electro-mechanical assembly,
wherein:
the at least one PUT outputs signals to the processor; and
the processor determines touch events at the outer surface of the metallic cover member in accordance with the signals.

3. The touch-sensing system of claim 2, wherein:
the processor is mounted to the circuit substrate.

4. The opto-electro-mechanical assembly of claim 1, wherein:
the solid light-transmitting and sound-transmitting member comprises a light-guide element, the metallic cover member overlying the light-guide element;
the light emitted from the solid-state light source is guided in the light-guide element between a first major surface and a second major surface opposite the first major surface and is extracted from the light-guide element towards the cover aperture; and
the first major surface is closer than the second major surface to the metallic cover member.

5. The opto-electro-mechanical assembly of claim 4, wherein:
the solid-state light source is positioned at an edge of the light-guide element.

6. The opto-electro-mechanical assembly of claim 4, wherein:
the solid-state light source is at least partly molded into the light-guide element.

7. The opto-electro-mechanical assembly of claim 4, wherein:
the light-guide element overlies the at least one PUT, the at least one PUT being oriented to emit ultrasound waves through the second major surface, and then through the first major surface, to the cover aperture.

8. The opto-electro-mechanical assembly of claim 4, wherein:
the at least one PUT is at least partly molded into the light-guide element.

9. The opto-electro-mechanical assembly of claim 4, wherein:
the circuit substrate is a flexible circuit substrate or a printed circuit board substrate.

10. The opto-electro-mechanical assembly of claim 4, wherein:
the solid-state light source and the at least one PUT are mounted to opposite sides of the circuit substrate.

11. The opto-electro-mechanical assembly of claim 10, wherein:
the opto-electro-mechanical assembly further comprises (1) an adhesive adhering the at least one PUT and the circuit substrate and/or (2) an acoustic impedance-matching material between the at least one PUT and the circuit substrate.

12. The opto-electro-mechanical assembly of claim 4, wherein:
the circuit substrate is molded into the light-guide element.

13. The opto-electro-mechanical assembly of claim 12, wherein:
the solid-state light source and the at least one PUT are molded into the light-guide element.

14. The opto-electro-mechanical assembly of claim 4, wherein:
the first major surface of the light-guide element is attached to an inner surface of the metallic cover member.

15. The opto-electro-mechanical assembly of claim 4, wherein:
the solid light-transmitting and sound-transmitting member further comprises an adhesive adhering the light-guide element and the metallic cover member and/or an acoustic impedance-matching material between the light-guide element and the metallic cover member.

16. The opto-electro-mechanical assembly of claim 4, wherein:
the metallic cover member is at least partly molded in the light-guide element.

17. The opto-electro-mechanical assembly of claim 4, wherein:
a surface of the at least one PUT is attached to the second major surface of the light-guide element.

18. The opto-electro-mechanical assembly of claim 17, wherein:
the surface is reflective and is configured to reflect the light emitted from the solid-state light source towards the cover aperture.

19. The opto-electro-mechanical assembly of claim 4, wherein:
the solid light-transmitting and sound-transmitting member further comprises an adhesive adhering the at least one PUT and the light-guide element and/or an acoustic impedance-matching material between the at least one PUT and the light-guide element.

20. The opto-electro-mechanical assembly of claim 1, wherein:
the metallic cover member overlies the at least one PUT, the at least one PUT being oriented to emit ultrasound waves to the cover aperture;
the at least one PUT has a PUT aperture;
the at least one PUT overlies the solid-state light source;
light emitted from the solid-state light source travels through the PUT aperture towards the cover aperture; and
the solid light-transmitting and sound-transmitting member comprises an adhesive adhering the at least one PUT to the metallic cover member and/or an acoustic impedance-matching material between the at least one PUT and the metallic cover member.

21. The opto-electro-mechanical assembly of claim 1, wherein:
the at least one PUT is part of an array of piezoelectric capacitors;
each of the piezoelectric capacitors of the array is configured as one or more of the following:
a transmitting-type PUT,
a receiving-type PUT, and
a piezoelectric force-measuring element (PFE); and
the piezoelectric capacitors are connected to the circuit substrate.

22. The opto-electro-mechanical assembly of claim 21, wherein:
the piezoelectric layer is commonly shared among the piezoelectric capacitors.

23. The opto-electro-mechanical assembly of claim 21, wherein:
each of the piezoelectric capacitors comprise a common electrode and an individual electrode;
the common electrode is shared among the piezoelectric capacitors; and
the individual electrode of each of the piezoelectric capacitors is connected to a respective position on the circuit substrate.

24. The opto-electro-mechanical assembly of claim 1, wherein:
the solid light-transmitting and sound-transmitting member comprises a light-guide element, the metallic cover member overlying the light-guide element;
the solid-state light source is positioned to emit light into the light-guide element; and
the at least one PUT is oriented such that ultrasound waves emitted by the at least one PUT are reflected at at least one surface of the light-guide element before reaching the cover aperture.
